(19) United States
(12) Patent Application Publication
(10) Pub. No.: US 2025/0107435 A1
(43) Pub. Date: Mar. 27, 2025

(54) ORGANIC ELECTRIC ELEMENT WITH MIXED HOST SYSTEM

(71) Applicant: Merck Patent GmbH, Darmstadt (DE)

(72) Inventors: Sebastian MEYER, Darmstadt (DE); Rouven LINGE, Darmstadt (DE); Miriam ENGEL, Darmstadt (DE); Sebastian STOLZ, Darmstadt (DE)

(21) Appl. No.: 18/729,906

(22) PCT Filed: Jan. 17, 2023
(86) PCT No.: PCT/EP2023/050918

§ 371 Date: Jul. 18, 2024

(30) Foreign Application Priority Data
Jan. 20, 2022 (EP) 22152450.7

(51) Int. Cl. H10K 85/60; C09K 11/02; C09K 11/06; H10K 50/11; H10K 50/18; H10K 71/13; H10K 101/00

(52) U.S. Cl. CPC H10K 85/626; C09K 11/02; C09K 11/06; H10K 85/615; H10K 85/622; H10K 85/624; H10K 85/653; H10K 85/654; H10K 85/6574; C09K 2211/1011; C09K 2211/1018; H10K 50/11; H10K 50/18; H10K 71/13; H10K 2101/90

(57) ABSTRACT

The present invention refers to an organic electric element comprising a mixed host system based on anthracene and a hole-blocking compound comprising a six-membered ring containing at least one Nitrogen atom, the six membered ring being linked to a moiety of two benzene rings being fused to a central 5-membered heterocycle containing either a Sulphur or an Oxygen atom.

The present invention refers to an organic electric element comprising a mixed host system based on anthracene and a hole-blocking compound comprising a six-membered ring containing at least one Nitrogen atom, the six membered ring being linked to a moiety of two benzene rings being fused to a central 5-membered heterocycle containing either a Sulphur or an Oxygen atom.

The structure of organic electric elements, such as organic electroluminescent devices (OLEDs) in which organic semiconductors are employed as functional materials is well-known and described, for example, in U.S. Pat. Nos. 4,539,507, 5,151,629, EP 0676461 and WO 98/27136.

Although present in the market for quite some time, the development of such devices with improved performance properties is still the subject of intensive research. Of particular importance, especially in view of the broad commercial use of OLEDs, are the lifetime, the efficiency and the operating voltage of the OLED as well as the color values achieved, especially when it comes to blue-emitting OLEDs.

One starting point for achieving the envisioned improvement of OLEDs is the choice of functional compounds employed in the OLED. The light-emitting compound in the light-emitting layer of an OLED is in most cases employed in combination with a second compound which does not emit light. The second compound is usually referred to as matrix or host compound. A number of host compounds are known in the art, including host compounds comprising a mixture of deuterated and non-deuterated host compounds, as for example, described in WO 2020/080416 which discloses an organic electroluminescence element with a positive electrode, a negative electrode, and at least one light-emitting layer between the positive electrode and the negative electrode, wherein the light-emitting layer includes a first host material, a second host material, and a dopant material; the first host material is a compound having at least one deuterium atom; and the light-emitting layer includes the first host material at a proportion of 1 mass % or more.

Other examples of matrix materials include carbazole derivatives (for example in accordance with WO 2014/015931), indolocarbazole derivatives (for example in accordance with WO 2007/063754 or WO 2008/056746) or indenocarbazole derivatives (for example in accordance with WO 2010/136109 or WO 2011/000455), in particular those which are substituted by electron-deficient heteroaromatic compounds, such as triazine. Furthermore, for example, bisdibenzofuran derivatives (for example in accordance with EP 2301926) are used as matrix materials for phosphorescent emitters. WO 2011/057706 discloses carbazole derivatives which are substituted by two triphenyltriazine groups.

In particular, WO 2015/169412 describes carbazole, dibenzofuran, dibenzothiophene and fluorene derivatives which are substituted by electron-deficient heteroaromatic groups, in particular for use as triplet matrix materials in organic electroluminescent devices.

However, there is still the need for further improved OLEDs, in particular with regard to lifetime of blue OLEDs. The present invention is thus based on the technical object of providing organic electric elements which show improved lifetime over the devices of the prior art.

In pursuing the above-defined object, it was surprisingly found that the properties could be improved by proper combination of the host material of the light-emitting layer with the other functional compounds in the OLED, in particular the hole-blocking compound.

In a first aspect, the present invention thus relates to an organic electric element comprising:
an anode;
a cathode;
at least one light-emitting layer between the anode and the cathode, the light emitting layer comprising a mixed host system of a first anthracene compound (Ant1) and a second anthracene compound (Ant2) wherein at least one of Ant1 and Ant2 is deuterated; and
at least one hole-blocking layer between the cathode and the light-emitting layer, the hole-blocking layer comprising at least one hole-blocking compound (EG) comprising a six membered ring containing at least one Nitrogen atom, the six membered ring being linked to a moiety of two benzene rings being fused to a central 5-membered heterocycle containing either a Sulphur or an Oxygen atom.

The following definitions of chemical groups apply for the purpose of the present invention if not otherwise specified:

A deuterium atom is labeled “D” or “d”.

R stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R′)₂, Ge(R′)₂, Sn(R′)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R may form an aliphatic or aromatic ring system together, which may be substituted by one or more radicals R′;

R′ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms.

An aryl group in the sense of this invention contains 5 to 60 aromatic ring atoms, preferably 6 to 40 aromatic ring atoms, more preferably 6 to 20 aromatic ring atoms; a heteroaryl group in the sense of this invention contains 5 to 60 aromatic ring atoms, preferably 5 to 40 aromatic ring atoms, more preferably 5 to 20 aromatic ring atoms, at least one of which is a heteroatom. The heteroatoms are preferably selected from N, O and S. This represents the basic definition. If other preferences are indicated in the description of the present invention, for example with respect to the number of aromatic ring atoms or the heteroatoms present, these apply.

An aryl group or heteroaryl group here is taken to mean either a simple aromatic ring, i.e. benzene, or a simple heteroaromatic ring, for example pyridine, pyrimidine or thiophene, or a condensed (annellated) aromatic or heteroaromatic polycycle, for example naphthalene, phenanthrene, quinoline or carbazole. A condensed (annellated) aromatic or heteroaromatic polycycle in the sense of the present application consists of two or more simple aromatic or heteroaromatic rings condensed with one another.

An aryl or heteroaryl group, which may in each case be substituted by the above-mentioned radicals and which may be linked to the aromatic or heteroaromatic ring system via any desired positions, is taken to mean, in particular, groups derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, iso-benzofuran, dibenzofuran, thiophene, benzothiophene, isobenzothiophene, dibenzothiophene, pyrrole, indole, isoindole, carbazole, pyridine, quinoline, iso-quinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazin-imidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxa-diazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aryloxy group in accordance with the definition of the present invention is taken to mean an aryl group, as defined above, which is bonded via an oxygen atom. An analogous definition applies to heteroaryloxy groups.

An aromatic ring system in the sense of this invention contains 5 to 60 C atoms in the ring system, preferably 6 to 40 C atoms, more preferably 6 to 20 C atoms. A heteroaromatic ring system in the sense of this invention contains 5 to 60 aromatic ring atoms, preferably 5 to 40 aromatic ring atoms, more preferably 5 to 20 aromatic ring atoms, at least one of which is a heteroatom. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit (preferably less than 10% of the atoms other than H), such as, for example, an sp³-hybridised C, Si, N or O atom, an sp²-hybridised C or N atom or an sp-hybridised C atom. Thus, for example, systems such as 9,9′-spirobifluorene, 9,9′-diarylfluorene, triarylamine, diaryl ether, stilbene, etc., are also intended to be taken to be aromatic ring systems in the sense of this invention, as are systems in which two or more aryl groups are connected, for example, by a linear or cyclic alkyl, alkenyl or alkynyl group or by a silyl group. Furthermore, systems in which two or more aryl or heteroaryl groups are linked to one another via single bonds are also taken to be aromatic or heteroaromatic ring systems in the sense of this invention, such as, for example, systems such as biphenyl, terphenyl or diphenyl-triazine.

An aromatic or heteroaromatic ring system having 5-60 aromatic ring atoms, which may in each case also be substituted by radicals as defined above and which may be linked to the aromatic or heteroaromatic group via any desired positions, is taken to mean, in particular, groups derived from benzene, naphthalene, anthracene, benzanthracene, phenanthrene, benzophenanthrene, pyrene, chrysene, perylene, fluoranthene, naphthacene, pentacene, benzopyrene, biphenyl, bi-phenylene, terphenyl, terphenylene, quaterphenyl, fluorene, spirobifluorene, dihydrophenanthrene, dihydropyrene, tetrahydropyrene, cis- or trans-indenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxa-diazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole, or combinations of these groups.

For the purposes of the present invention, a straight-chain alkyl group having 1 to 40 C atoms or a branched or cyclic alkyl group having 3 to 40 C atoms or an alkenyl or alkynyl group having 2 to 40 C atoms, in which, in addition, individual H atoms or CH₂ groups may be substituted by the groups mentioned above under the definition of the radicals, is preferably taken to mean the radicals methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl. An alkoxy or thioalkyl group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio.

The formulation that two or more radicals may form a ring with one another is, for the purposes of the present application, intended to be taken to mean, inter alia, that the two radicals are linked to one another by a chemical bond. This is illustrated by the following schemes:

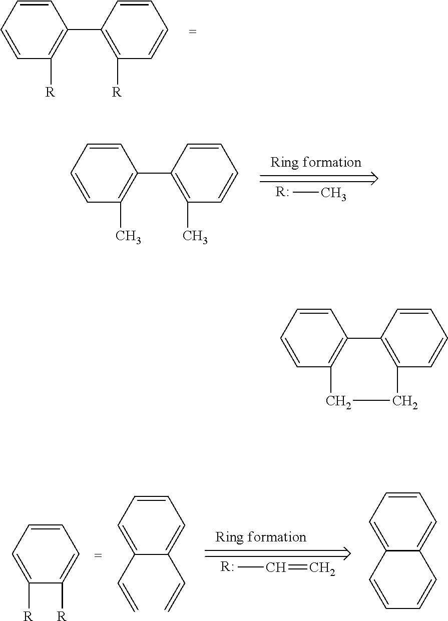

Furthermore, however, the above-mentioned formulation is also intended to be taken to mean that, in the case where one of the two radicals represents hydrogen, the second radical is bonded at the position to which the hydrogen atom was bonded, with formation of a ring. This is illustrated by the following scheme:

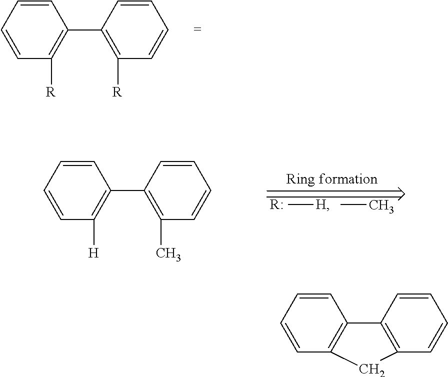

When two radicals form a ring with one another, then it is preferred that the two radicals are adjacent radicals. Adjacent radicals in the sense of the present invention are radicals which are bonded to atoms which are linked directly to one another or which are bonded to the same atom.

The mixed host system of the electric element according to the present invention is based on a mixture of deuterated and non-deuterated anthracene systems. Although generally known as host systems in OLEDs it is believed that in particular the inventive combination with the specific hole-blocking compound results in organic electric elements, in particular blue light-emitting OLEDs with improved lifetime. The specific compounds as employed in the organic electric element of the present invention will be described in more detail as follows:

### I. Host System

In preferred embodiment of the present invention, Ant1 is represented by formula I:

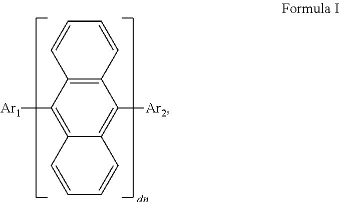

and Ant2 is represented by Formula II:

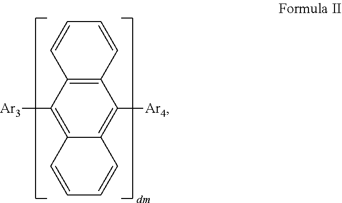

with
d or D depicting the number of deuterium substituents on the anthracenyl group;
n is an integer from 1 to 8;
m is an integer from 0 to 8;
Ar1, Ar2, Ar3 and Ar4 are, on each occurrence, identically or differently, an aromatic or heteroaromatic ring system having 5 to 60 aromatic ring atoms, which may in each case also be substituted by one or more radicals R;
R stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R′)₂, Ge(R′)₂, Sn(R′)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R may form an aliphatic or aromatic ring system together, which may be substituted by one or more radicals R′;
Ar is, on each occurrence, identically or differently, an aromatic or heteroaromatic ring system having 5 to 60 aromatic ring atoms, which may in each case also be substituted by one or more radicals R′;
R′ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms.

In a further preferred embodiment, each of Ar1, Ar2, Ar3 and Ar4 stand on each occurrence, identically or differently, for phenyl, biphenyl, terphenyl, quaterphenyl, fluorene, spirobifluorene, naphthalene, anthracene, phenanthrene, triphenylene, fluoranthene, tetracene, chrysene, benzanthracene, benzophenanthracene, pyrene or perylene, dibenzofuran, carbazole and dibenzothiophene, each of which may be substituted by one or more radicals R′ at any free positions; and where Art, Ar2, Ar3 and Ar4 might also be a combination of two or more of the previously cited groups. In a particular preferred embodiment, R′ is selected from H or D.

Although any of Ar1, Ar2, Ar3 and Ar4 may be substituted with deuterium atoms, preference is given to an embodiment of the present invention wherein at least one of Ant1 or Ant2 comprises a fully deuterated anthracenyl group. In an especially preferred embodiment, only one of Ant1 and Ant2 comprises a fully deuterated anthracenyl group.

Suitable examples of compounds Ant1 are depicted in the table below:

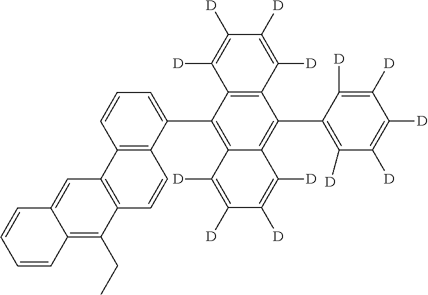 [SMILES: [2H]c1c([2H])c([2H])c(-c2c3c([2H])c([2H])c([2H])c([2H])c3c(-c3cccc4c3ccc3c(CC)c5ccccc5cc34)c3c([2H])c([2H])c([2H])c([2H])c23)c([2H])c1[2H]]

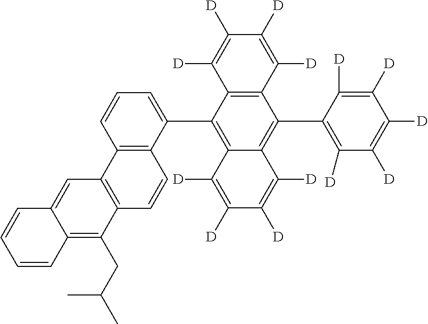 [SMILES: [2H]c1c([2H])c([2H])c(-c2c3c([2H])c([2H])c([2H])c([2H])c3c(-c3cccc4c3ccc3c(CC(C)C)c5ccccc5cc34)c3c([2H])c([2H])c([2H])c([2H])c23)c([2H])c1[2H]]

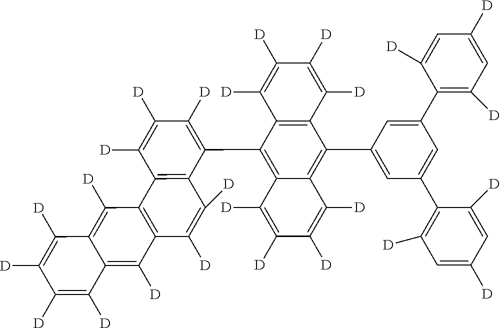 [SMILES: [2H]c1cc([2H])c(-c2cc(-c3c([2H])cc([2H])cc3[2H])cc(-c3c4c([2H])c([2H])c([2H])c([2H])c4c(-c4c([2H])c([2H])c([2H])c5c4c([2H])c([2H])c4c([2H])c6c([2H])c([2H])c([2H])c([2H])c6c([2H])c45)c4c([2H])c([2H])c([2H])c([2H])c34)c2)c([2H])c1]

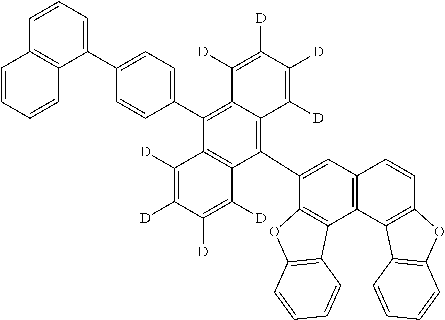 [SMILES: [2H]c1c([2H])c([2H])c2c(-c3cc4ccc5oc6ccccc6c5c4c4c3oc3ccccc34)c3c([2H])c([2H])c([2H])c([2H])c3c(-c3ccc(-c4cccc5ccccc45)cc3)c2c1[2H]]

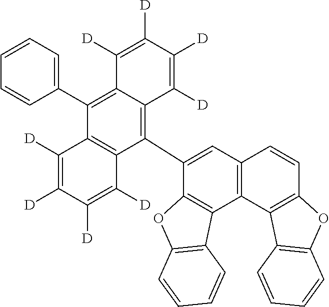 [SMILES: [2H]c1c([2H])c([2H])c2c(-c3cc4ccc5oc6ccccc6c5c4c4c3oc3ccccc34)c3c([2H])c([2H])c([2H])c([2H])c3c(-c3ccccc3)c2c1[2H]]

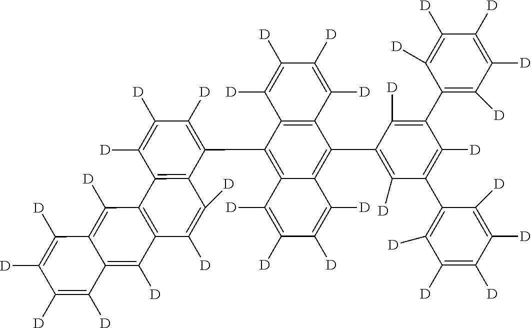 [SMILES: [2H]c1c([2H])c([2H])c(-c2c([2H])c(-c3c([2H])c([2H])c([2H])c([2H])c3[2H])c([2H])c(-c3c4c([2H])c([2H])c([2H])c([2H])c4c(-c4c([2H])c([2H])c([2H])c5c4c([2H])c([2H])c4c([2H])c6c([2H])c([2H])c([2H])c([2H])c6c([2H])c45)c4c([2H])c([2H])c([2H])c([2H])c34)c2[2H])c([2H])c1[2H]]

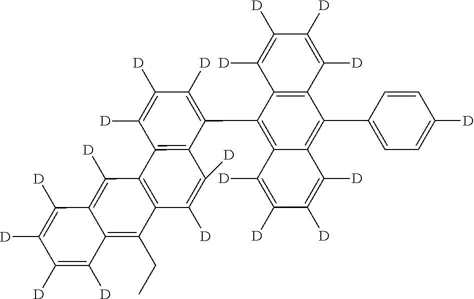 [SMILES: [2H]c1ccc(-c2c3c([2H])c([2H])c([2H])c([2H])c3c(-c3c([2H])c([2H])c([2H])c4c3c([2H])c([2H])c3c(CC)c5c([2H])c([2H])c([2H])c([2H])c5c([2H])c34)c3c([2H])c([2H])c([2H])c([2H])c23)cc1]

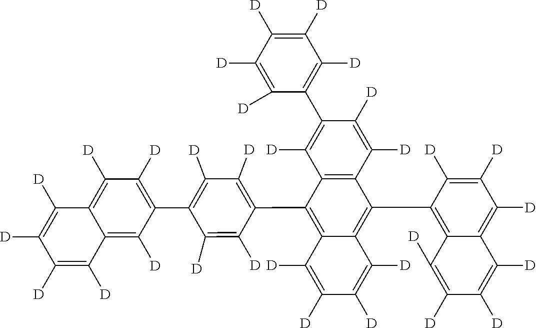 [SMILES: [2H]c1c([2H])c([2H])c(-c2c([2H])c([2H])c3c(-c4c([2H])c([2H])c([2H])c5c([2H])c([2H])c([2H])c([2H])c45)c4c([2H])c([2H])c([2H])c([2H])c4c(-c4c([2H])c([2H])c(-c5c([2H])c([2H])c6c([2H])c([2H])c([2H])c([2H])c6c5[2H])c([2H])c4[2H])c3c2[2H])c([2H])c1[2H]]

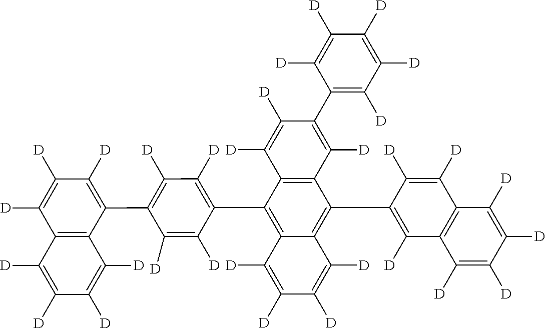 [SMILES: [2H]c1c([2H])c([2H])c(-c2c([2H])c([2H])c3c(-c4c([2H])c([2H])c(-c5c([2H])c([2H])c([2H])c6c([2H])c([2H])c([2H])c([2H])c56)c([2H])c4[2H])c4c([2H])c([2H])c([2H])c([2H])c4c(-c4c([2H])c([2H])c5c([2H])c([2H])c([2H])c([2H])c5c4[2H])c3c2[2H])c([2H])c1[2H]]

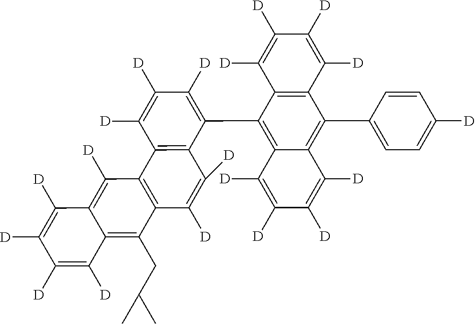 [SMILES: [2H]c1ccc(-c2c3c([2H])c([2H])c([2H])c([2H])c3c(-c3c([2H])c([2H])c([2H])c4c3c([2H])c([2H])c3c(CC(C)C)c5c([2H])c([2H])c([2H])c([2H])c5c([2H])c34)c3c([2H])c([2H])c([2H])c([2H])c23)cc1]

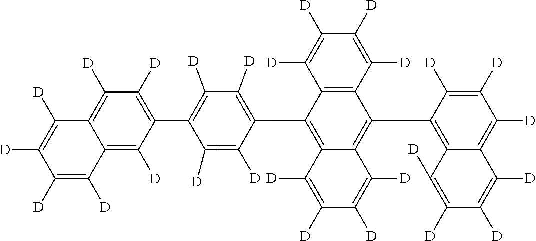 [SMILES: [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1c([2H])c([2H])c2c([2H])c([2H])c([2H])c([2H])c2c1[2H]]

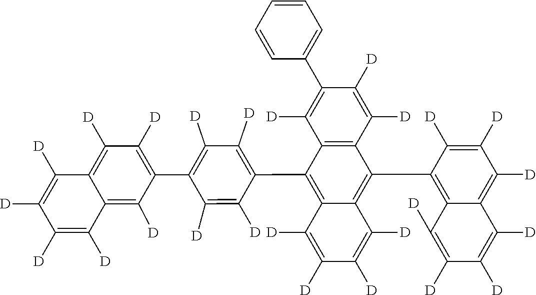 [SMILES: [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c(-c4ccccc4)c([2H])c23)c([2H])c([2H])c1-c1c([2H])c([2H])c2c([2H])c([2H])c([2H])c([2H])c2c1[2H]]

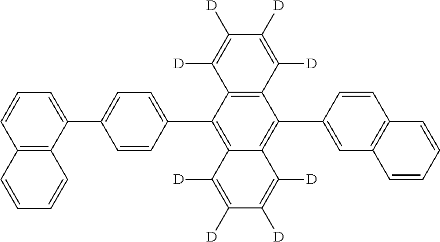 [SMILES: [2H]c1c([2H])c([2H])c2c(-c3ccc4ccccc4c3)c3c([2H])c([2H])c([2H])c([2H])c3c(-c3ccc(-c4cccc5ccccc45)cc3)c2c1[2H]]

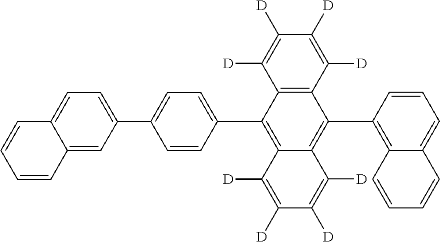 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H]]

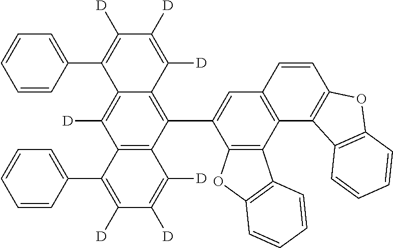 [SMILES: [2H]c1c([2H])c(-c2ccccc2)c2c([2H])c3c(-c4ccccc4)c([2H])c([2H])c([2H])c3c(-c3cc4ccc5oc6ccccc6c5c4c4c3oc3ccccc34)c2c1[2H]]

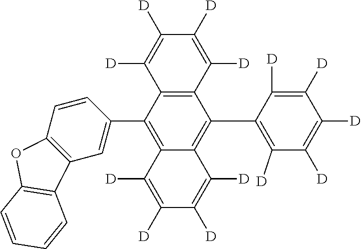 [SMILES: [2H]c1c([2H])c([2H])c(-c2c3c([2H])c([2H])c([2H])c([2H])c3c(-c3ccc4oc5ccccc5c4c3)c3c([2H])c([2H])c([2H])c([2H])c23)c([2H])c1[2H]]

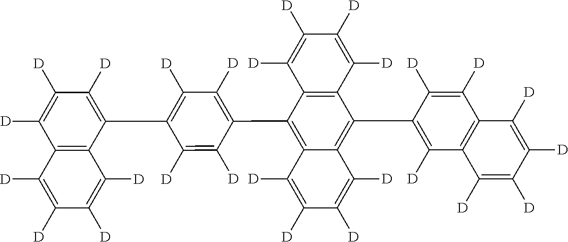 [SMILES: [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c([2H])c2c([2H])c([2H])c([2H])c([2H])c12]

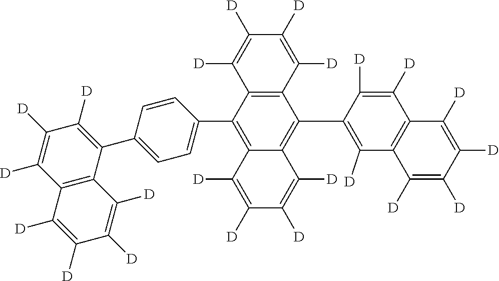 [SMILES: [2H]c1c([2H])c([2H])c2c([2H])c(-c3c4c([2H])c([2H])c([2H])c([2H])c4c(-c4ccc(-c5c([2H])c([2H])c([2H])c6c([2H])c([2H])c([2H])c([2H])c56)cc4)c4c([2H])c([2H])c([2H])c([2H])c34)c([2H])c([2H])c2c1[2H]]

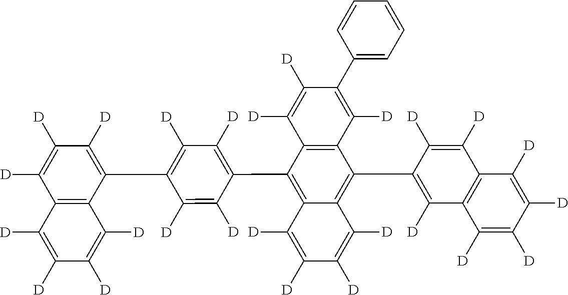 [SMILES: [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c(-c4ccccc4)c([2H])c([2H])c23)c([2H])c([2H])c1-c1c([2H])c([2H])c([2H])c2c([2H])c([2H])c([2H])c([2H])c12]

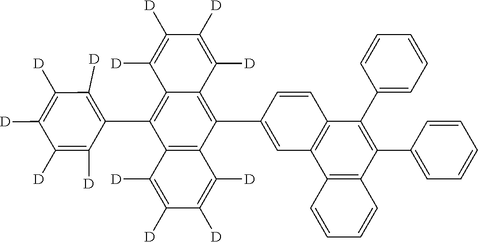 [SMILES: [2H]c1c([2H])c([2H])c(-c2c3c([2H])c([2H])c([2H])c([2H])c3c(-c3ccc4c(-c5ccccc5)c(-c5ccccc5)c5ccccc5c4c3)c3c([2H])c([2H])c([2H])c([2H])c23)c([2H])c1[2H]]

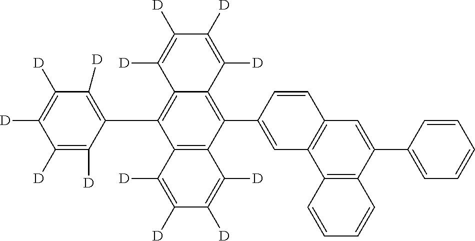 [SMILES: [2H]c1c([2H])c([2H])c(-c2c3c([2H])c([2H])c([2H])c([2H])c3c(-c3ccc4cc(-c5ccccc5)c5ccccc5c4c3)c3c([2H])c([2H])c([2H])c([2H])c23)c([2H])c1[2H]]

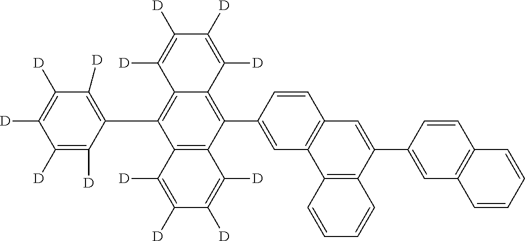 [SMILES: [2H]c1c([2H])c([2H])c(-c2c3c([2H])c([2H])c([2H])c([2H])c3c(-c3ccc4cc(-c5ccc6ccccc6c5)c5ccccc5c4c3)c3c([2H])c([2H])c([2H])c([2H])c23)c([2H])c1[2H]]

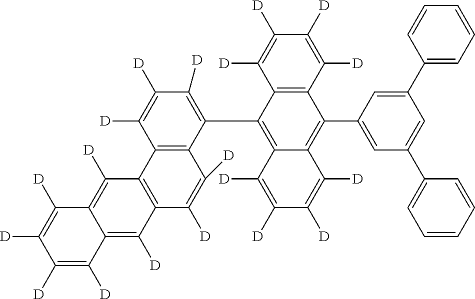 [SMILES: [2H]c1c([2H])c([2H])c2c(-c3c([2H])c([2H])c([2H])c4c3c([2H])c([2H])c3c([2H])c5c([2H])c([2H])c([2H])c([2H])c5c([2H])c34)c3c([2H])c([2H])c([2H])c([2H])c3c(-c3cc(-c4ccccc4)cc(-c4ccccc4)c3)c2c1[2H]]

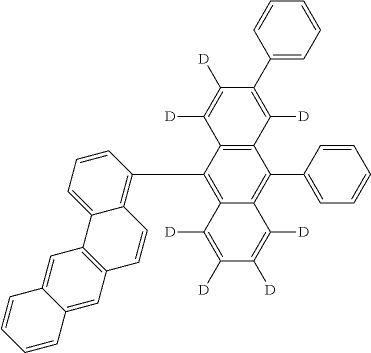 [SMILES: [2H]c1c([2H])c([2H])c2c(-c3cccc4c3ccc3cc5ccccc5cc34)c3c([2H])c([2H])c(-c4ccccc4)c([2H])c3c(-c3ccccc3)c2c1[2H]]

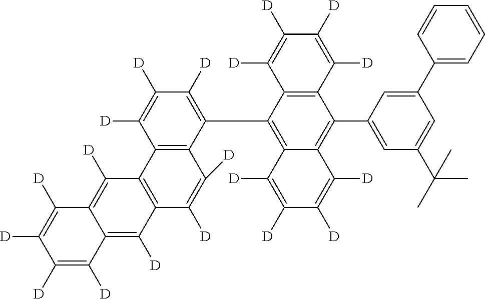 [SMILES: [2H]c1c([2H])c([2H])c2c(-c3c([2H])c([2H])c([2H])c4c3c([2H])c([2H])c3c([2H])c5c([2H])c([2H])c([2H])c([2H])c5c([2H])c34)c3c([2H])c([2H])c([2H])c([2H])c3c(-c3cc(-c4ccccc4)cc(C(C)(C)C)c3)c2c1[2H]]

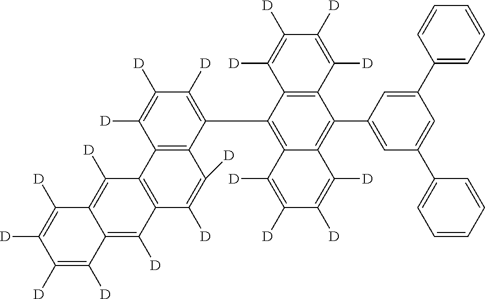 [SMILES: [2H]c1c([2H])c([2H])c2c(-c3c([2H])c([2H])c([2H])c4c3c([2H])c([2H])c3c([2H])c5c([2H])c([2H])c([2H])c([2H])c5c([2H])c34)c3c([2H])c([2H])c([2H])c([2H])c3c(-c3cc(-c4ccccc4)cc(-c4ccccc4)c3)c2c1[2H]]

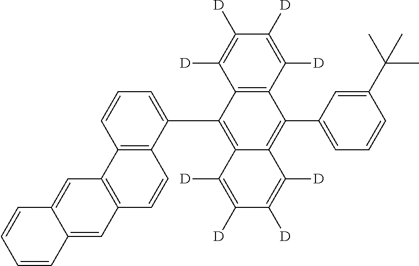 [SMILES: [2H]c1c([2H])c([2H])c2c(-c3cccc4c3ccc3cc5ccccc5cc34)c3c([2H])c([2H])c([2H])c([2H])c3c(-c3cccc(C(C)(C)C)c3)c2c1[2H]]

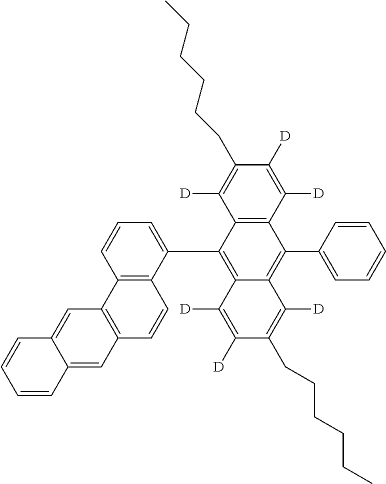 [SMILES: [2H]c1c(CCCCCC)c([2H])c2c(-c3cccc4c3ccc3cc5ccccc5cc34)c3c([2H])c([2H])c(CCCCCC)c([2H])c3c(-c3ccccc3)c2c1[2H]]

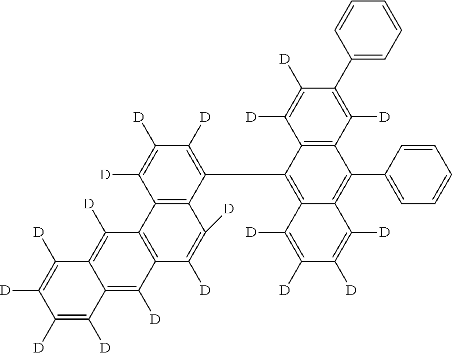 [SMILES: [2H]c1c([2H])c([2H])c2c(-c3c([2H])c([2H])c([2H])c4c3c([2H])c([2H])c3c([2H])c5c([2H])c([2H])c([2H])c([2H])c5c([2H])c34)c3c([2H])c([2H])c(-c4ccccc4)c([2H])c3c(-c3ccccc3)c2c1[2H]]

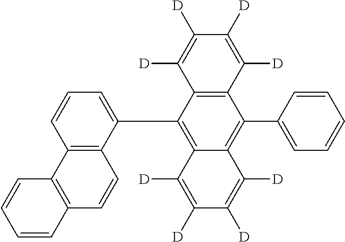 [SMILES: [2H]c1c([2H])c([2H])c2c(-c3cccc4c3ccc3ccccc34)c3c([2H])c([2H])c([2H])c([2H])c3c(-c3ccccc3)c2c1[2H]]

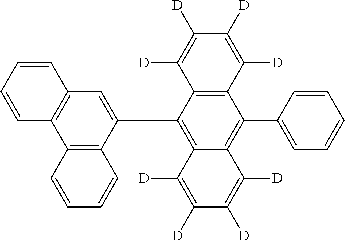 [SMILES: [2H]c1c([2H])c([2H])c2c(-c3cc4ccccc4c4ccccc34)c3c([2H])c([2H])c([2H])c([2H])c3c(-c3ccccc3)c2c1[2H]]

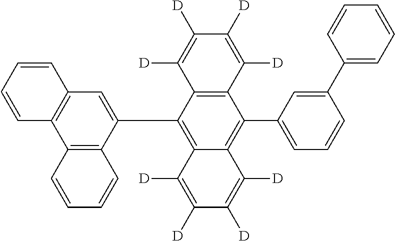 [SMILES: [2H]c1c([2H])c([2H])c2c(-c3cc4ccccc4c4ccccc34)c3c([2H])c([2H])c([2H])c([2H])c3c(-c3cccc(-c4ccccc4)c3)c2c1[2H]]

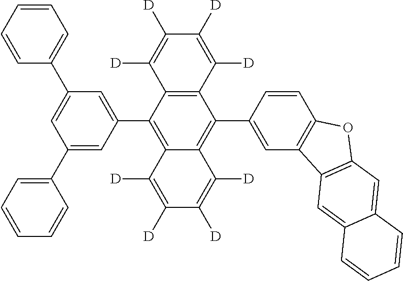 [SMILES: [2H]c1c([2H])c([2H])c2c(-c3ccc4oc5cc6ccccc6cc5c4c3)c3c([2H])c([2H])c([2H])c([2H])c3c(-c3cc(-c4ccccc4)cc(-c4ccccc4)c3)c2c1[2H]]

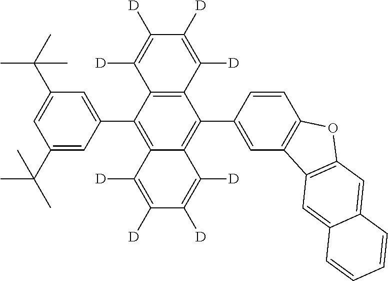 [SMILES: [2H]c1c([2H])c([2H])c2c(-c3ccc4oc5cc6ccccc6cc5c4c3)c3c([2H])c([2H])c([2H])c([2H])c3c(-c3cc(C(C)(C)C)cc(C(C)(C)C)c3)c2c1[2H]]

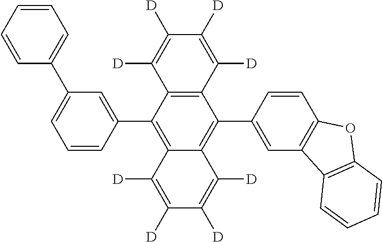 [SMILES: [2H]c1c([2H])c([2H])c2c(-c3ccc4oc5ccccc5c4c3)c3c([2H])c([2H])c([2H])c([2H])c3c(-c3cccc(-c4ccccc4)c3)c2c1[2H]]

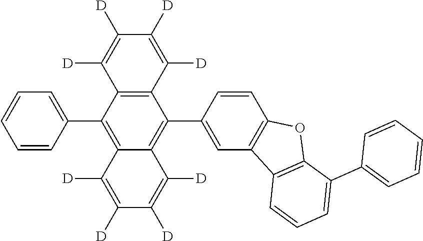 [SMILES: [2H]c1c([2H])c([2H])c2c(-c3ccc4oc5c(-c6ccccc6)cccc5c4c3)c3c([2H])c([2H])c([2H])c([2H])c3c(-c3ccccc3)c2c1[2H]]

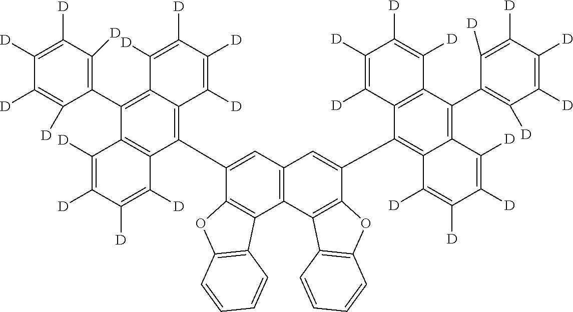 [SMILES: [2H]c1c([2H])c([2H])c(-c2c3c([2H])c([2H])c([2H])c([2H])c3c(-c3cc4cc(-c5c6c([2H])c([2H])c([2H])c([2H])c6c(-c6c([2H])c([2H])c([2H])c([2H])c6[2H])c6c([2H])c([2H])c([2H])c([2H])c56)c5oc6ccccc6c5c4c4c3oc3ccccc34)c3c([2H])c([2H])c([2H])c([2H])c23)c([2H])c1[2H]]

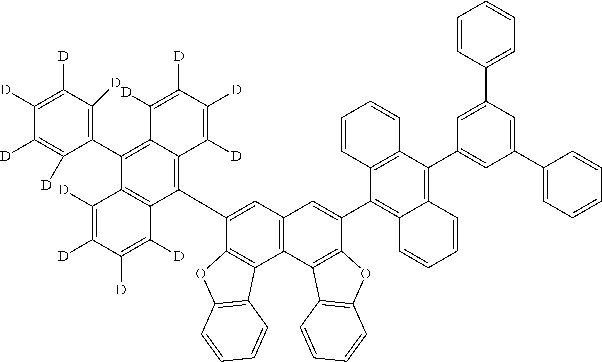 [SMILES: [2H]c1c([2H])c([2H])c(-c2c3c([2H])c([2H])c([2H])c([2H])c3c(-c3cc4cc(-c5c6ccccc6c(-c6cc(-c7ccccc7)cc(-c7ccccc7)c6)c6ccccc56)c5oc6ccccc6c5c4c4c3oc3ccccc34)c3c([2H])c([2H])c([2H])c([2H])c23)c([2H])c1[2H]]

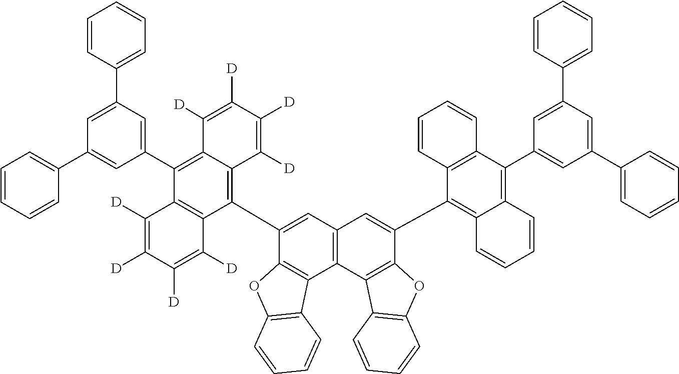 [SMILES: [2H]c1c([2H])c([2H])c2c(-c3cc4cc(-c5c6ccccc6c(-c6cc(-c7ccccc7)cc(-c7ccccc7)c6)c6ccccc56)c5oc6ccccc6c5c4c4c3oc3ccccc34)c3c([2H])c([2H])c([2H])c([2H])c3c(-c3cc(-c4ccccc4)cc(-c4ccccc4)c3)c2c1[2H]]

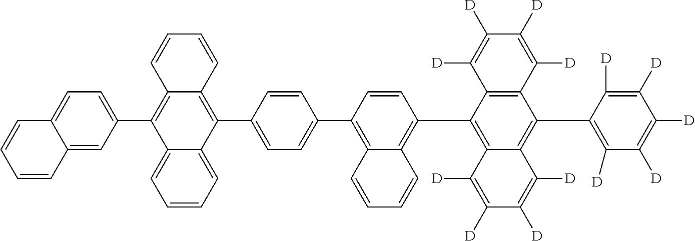 [SMILES: [2H]c1c([2H])c([2H])c(-c2c3c([2H])c([2H])c([2H])c([2H])c3c(-c3ccc(-c4ccc(-c5c6ccccc6c(-c6ccc7ccccc7c6)c6ccccc56)cc4)c4ccccc34)c3c([2H])c([2H])c([2H])c([2H])c23)c([2H])c1[2H]]

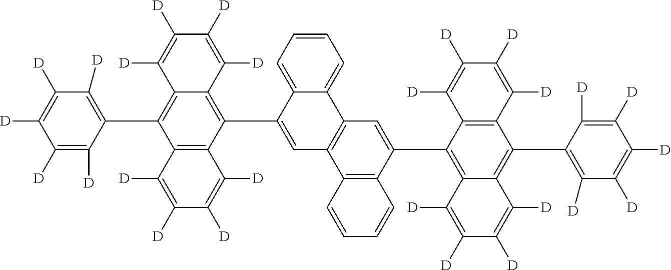 [SMILES: [2H]c1c([2H])c([2H])c(-c2c3c([2H])c([2H])c([2H])c([2H])c3c(-c3cc4c5ccccc5c(-c5c6c([2H])c([2H])c([2H])c([2H])c6c(-c6c([2H])c([2H])c([2H])c([2H])c6[2H])c6c([2H])c([2H])c([2H])c([2H])c56)cc4c4ccccc34)c3c([2H])c([2H])c([2H])c([2H])c23)c([2H])c1[2H]]

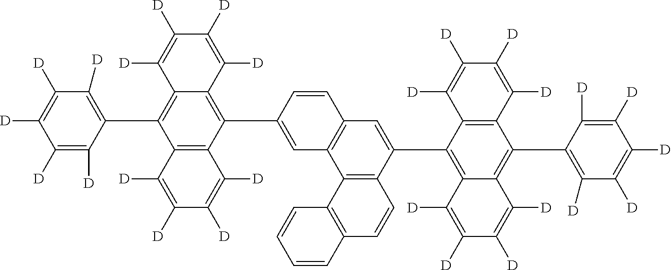 [SMILES: [2H]c1c([2H])c([2H])c(-c2c3c([2H])c([2H])c([2H])c([2H])c3c(-c3ccc4cc(-c5c6c([2H])c([2H])c([2H])c([2H])c6c(-c6c([2H])c([2H])c([2H])c([2H])c6[2H])c6c([2H])c([2H])c([2H])c([2H])c56)c5ccc6ccccc6c5c4c3)c3c([2H])c([2H])c([2H])c([2H])c23)c([2H])c1[2H]]

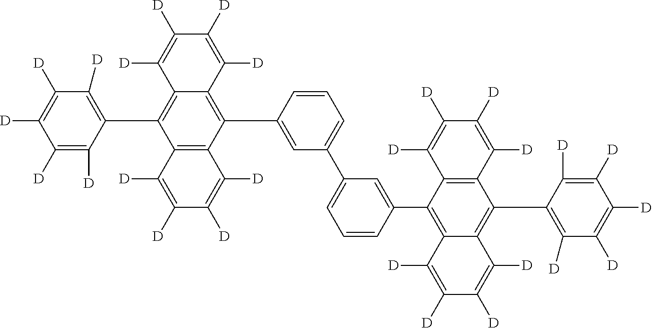 [SMILES: [2H]c1c([2H])c([2H])c(-c2c3c([2H])c([2H])c([2H])c([2H])c3c(-c3cccc(-c4cccc(-c5c6c([2H])c([2H])c([2H])c([2H])c6c(-c6c([2H])c([2H])c([2H])c([2H])c6[2H])c6c([2H])c([2H])c([2H])c([2H])c56)c4)c3)c3c([2H])c([2H])c([2H])c([2H])c23)c([2H])c1[2H]]

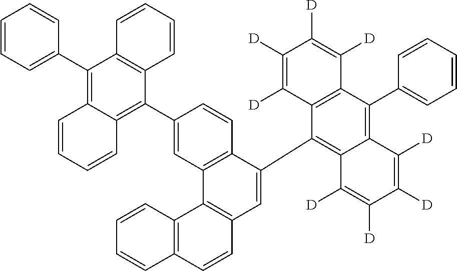 [SMILES: [2H]c1c([2H])c([2H])c2c(-c3cc4ccc5ccccc5c4c4cc(-c5c6ccccc6c(-c6ccccc6)c6ccccc56)ccc34)c3c([2H])c([2H])c([2H])c([2H])c3c(-c3ccccc3)c2c1[2H]]

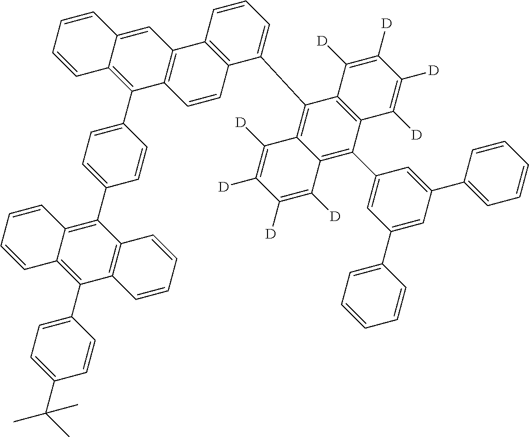 [SMILES: [2H]c1c([2H])c([2H])c2c(-c3cccc4c3ccc3c(-c5ccc(-c6c7ccccc7c(-c7ccc(C(C)(C)C)cc7)c7ccccc67)cc5)c5ccccc5cc34)c3c([2H])c([2H])c([2H])c([2H])c3c(-c3cc(-c4ccccc4)cc(-c4ccccc4)c3)c2c1[2H]]

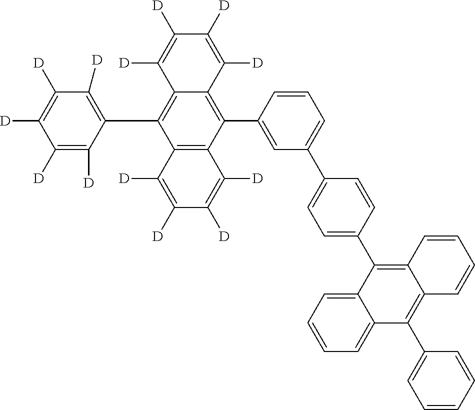 [SMILES: [2H]c1c([2H])c([2H])c(-c2c3c([2H])c([2H])c([2H])c([2H])c3c(-c3cccc(-c4ccc(-c5c6ccccc6c(-c6ccccc6)c6ccccc56)cc4)c3)c3c([2H])c([2H])c([2H])c([2H])c23)c([2H])c1[2H]]

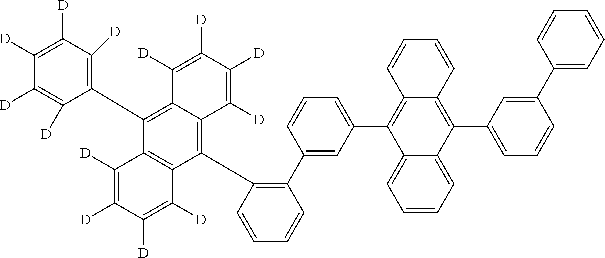 [SMILES: [2H]c1c([2H])c([2H])c(-c2c3c([2H])c([2H])c([2H])c([2H])c3c(-c3ccccc3-c3cccc(-c4c5ccccc5c(-c5cccc(-c6ccccc6)c5)c5ccccc45)c3)c3c([2H])c([2H])c([2H])c([2H])c23)c([2H])c1[2H]]

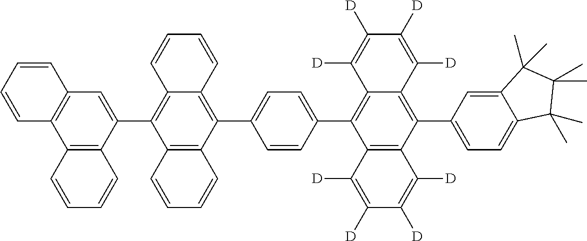 [SMILES: [2H]c1c([2H])c([2H])c2c(-c3ccc4c(c3)C(C)(C)C(C)(C)C4(C)C)c3c([2H])c([2H])c([2H])c([2H])c3c(-c3ccc(-c4c5ccccc5c(-c5cc6ccccc6c6ccccc56)c5ccccc45)cc3)c2c1[2H]]

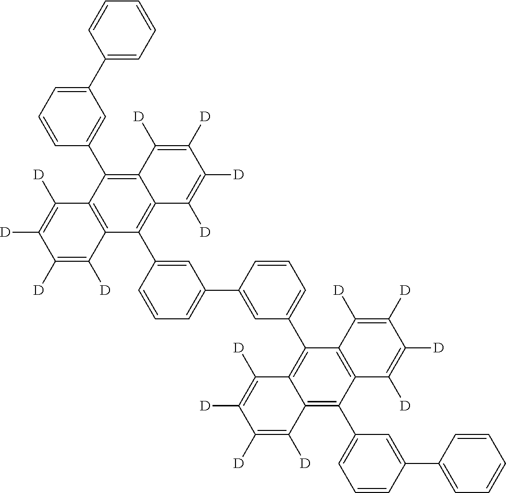 [SMILES: [2H]c1c([2H])c([2H])c2c(-c3cccc(-c4cccc(-c5c6c([2H])c([2H])c([2H])c([2H])c6c(-c6cccc(-c7ccccc7)c6)c6c([2H])c([2H])c([2H])c([2H])c56)c4)c3)c3c([2H])c([2H])c([2H])c([2H])c3c(-c3cccc(-c4ccccc4)c3)c2c1[2H]]

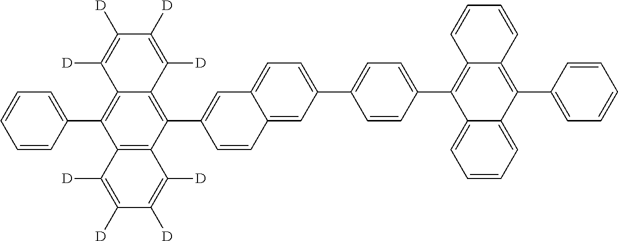 [SMILES: [2H]c1c([2H])c([2H])c2c(-c3ccc4cc(-c5ccc(-c6c7ccccc7c(-c7ccccc7)c7ccccc67)cc5)ccc4c3)c3c([2H])c([2H])c([2H])c([2H])c3c(-c3ccccc3)c2c1[2H]]

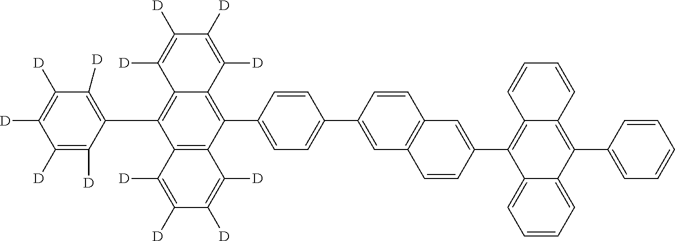 [SMILES: [2H]c1c([2H])c([2H])c(-c2c3c([2H])c([2H])c([2H])c([2H])c3c(-c3ccc(-c4ccc5cc(-c6c7ccccc7c(-c7ccccc7)c7ccccc67)ccc5c4)cc3)c3c([2H])c([2H])c([2H])c([2H])c23)c([2H])c1[2H]]

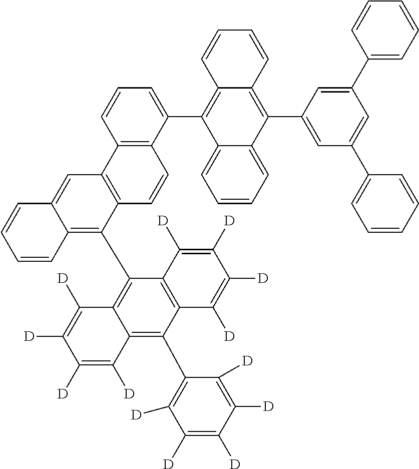 [SMILES: [2H]c1c([2H])c([2H])c(-c2c3c([2H])c([2H])c([2H])c([2H])c3c(-c3c4ccccc4cc4c3ccc3c(-c5c6ccccc6c(-c6cc(-c7ccccc7)cc(-c7ccccc7)c6)c6ccccc56)cccc34)c3c([2H])c([2H])c([2H])c([2H])c23)c([2H])c1[2H]]

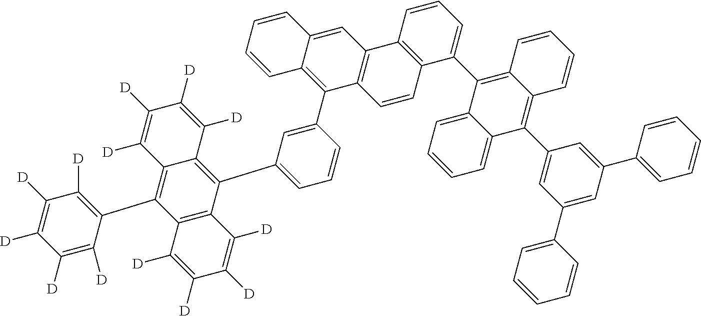 [SMILES: [2H]c1c([2H])c([2H])c(-c2c3c([2H])c([2H])c([2H])c([2H])c3c(-c3cccc(-c4c5ccccc5cc5c4ccc4c(-c6c7ccccc7c(-c7cc(-c8ccccc8)cc(-c8ccccc8)c7)c7ccccc67)cccc45)c3)c3c([2H])c([2H])c([2H])c([2H])c23)c([2H])c1[2H]]

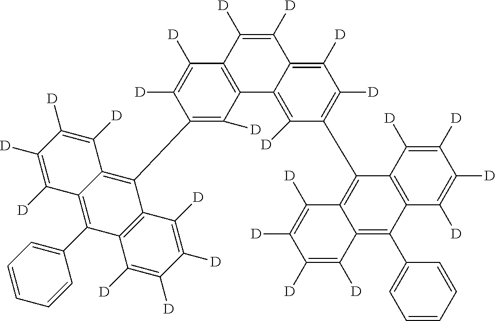 [SMILES: [2H]c1c([2H])c([2H])c2c(-c3c([2H])c([2H])c4c([2H])c([2H])c5c([2H])c([2H])c(-c6c7c([2H])c([2H])c([2H])c([2H])c7c(-c7ccccc7)c7c([2H])c([2H])c([2H])c([2H])c67)c([2H])c5c4c3[2H])c3c([2H])c([2H])c([2H])c([2H])c3c(-c3ccccc3)c2c1[2H]]

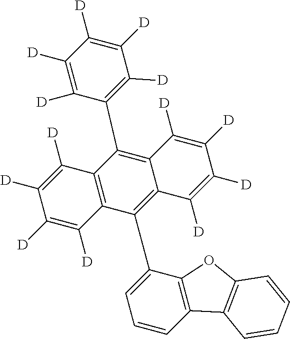 [SMILES: [2H]c1c([2H])c([2H])c(-c2c3c([2H])c([2H])c([2H])c([2H])c3c(-c3cccc4c3oc3ccccc34)c3c([2H])c([2H])c([2H])c([2H])c23)c([2H])c1[2H]]

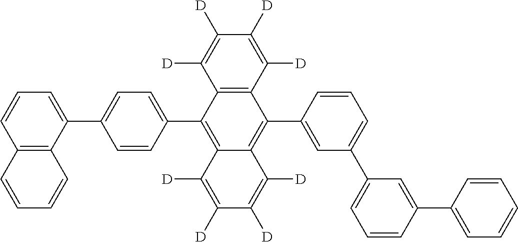 [SMILES: [2H]c1c([2H])c([2H])c2c(-c3cccc(-c4cccc(-c5ccccc5)c4)c3)c3c([2H])c([2H])c([2H])c([2H])c3c(-c3ccc(-c4cccc5ccccc45)cc3)c2c1[2H]]

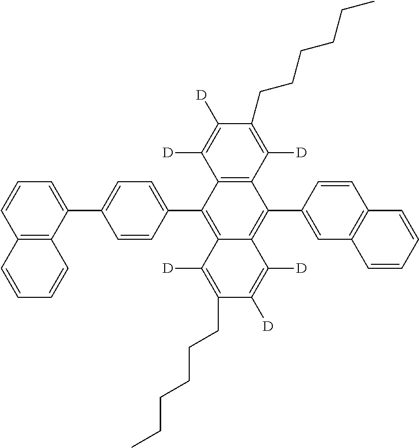 [SMILES: [2H]c1c(CCCCCC)c([2H])c2c(-c3ccc(-c4cccc5ccccc45)cc3)c3c([2H])c([2H])c(CCCCCC)c([2H])c3c(-c3ccc4ccccc4c3)c2c1[2H]]

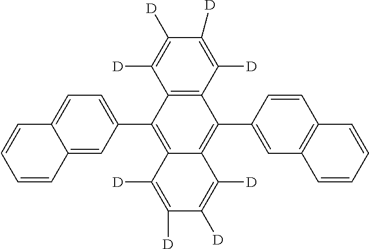 [SMILES: [2H]c1c([2H])c([2H])c2c(-c3ccc4ccccc4c3)c3c([2H])c([2H])c([2H])c([2H])c3c(-c3ccc4ccccc4c3)c2c1[2H]]

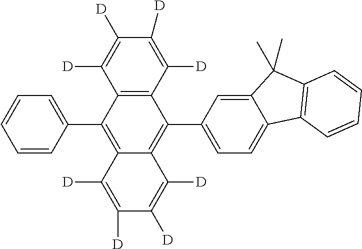 [SMILES: [2H]c1c([2H])c([2H])c2c(-c3ccc4c(c3)C(C)(C)c3ccccc3-4)c3c([2H])c([2H])c([2H])c([2H])c3c(-c3ccccc3)c2c1[2H]]

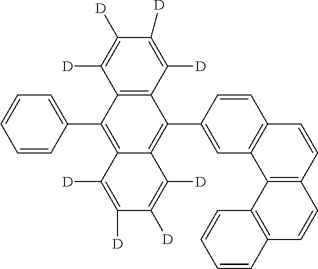 [SMILES: [2H]c1c([2H])c([2H])c2c(-c3ccc4ccc5ccc6ccccc6c5c4c3)c3c([2H])c([2H])c([2H])c([2H])c3c(-c3ccccc3)c2c1[2H]]

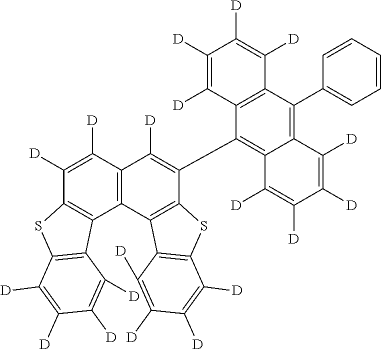 [SMILES: [2H]c1c([2H])c([2H])c2c(sc3c([2H])c([2H])c4c([2H])c(-c5c6c([2H])c([2H])c([2H])c([2H])c6c(-c6ccccc6)c6c([2H])c([2H])c([2H])c([2H])c56)c5sc6c([2H])c([2H])c([2H])c([2H])c6c5c4c32)c1[2H]]

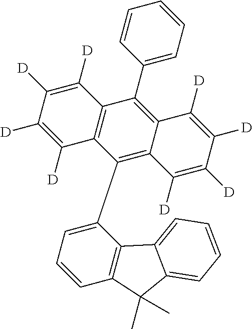 [SMILES: [2H]c1c([2H])c([2H])c2c(-c3cccc4c3-c3ccccc3C4(C)C)c3c([2H])c([2H])c([2H])c([2H])c3c(-c3ccccc3)c2c1[2H]]

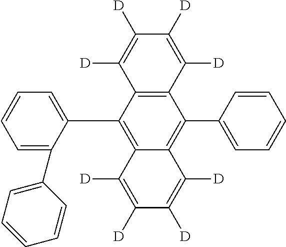 [SMILES: [2H]c1c([2H])c([2H])c2c(-c3ccccc3-c3ccccc3)c3c([2H])c([2H])c([2H])c([2H])c3c(-c3ccccc3)c2c1[2H]]

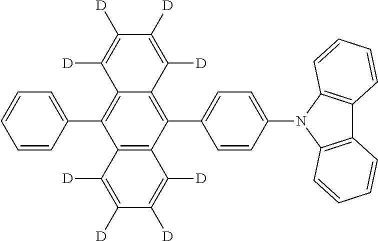 [SMILES: [2H]c1c([2H])c([2H])c2c(-c3ccc(-n4c5ccccc5c5ccccc54)cc3)c3c([2H])c([2H])c([2H])c([2H])c3c(-c3ccccc3)c2c1[2H]]

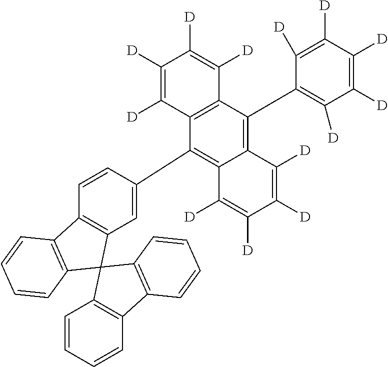 [SMILES: [2H]c1c([2H])c([2H])c(-c2c3c([2H])c([2H])c([2H])c([2H])c3c(-c3ccc4c(c3)C3(c5ccccc5-c5ccccc53)c3ccccc3-4)c3c([2H])c([2H])c([2H])c([2H])c23)c([2H])c1[2H]]

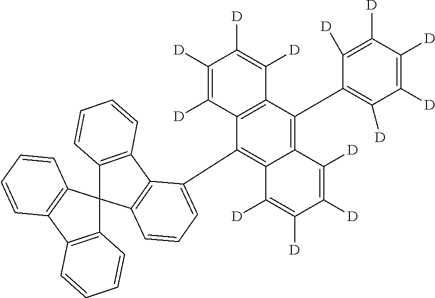 [SMILES: [2H]c1c([2H])c([2H])c(-c2c3c([2H])c([2H])c([2H])c([2H])c3c(-c3cccc4c3-c3ccccc3C43c4ccccc4-c4ccccc43)c3c([2H])c([2H])c([2H])c([2H])c23)c([2H])c1[2H]]

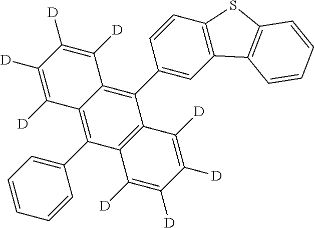 [SMILES: [2H]c1c([2H])c([2H])c2c(-c3ccc4sc5ccccc5c4c3)c3c([2H])c([2H])c([2H])c([2H])c3c(-c3ccccc3)c2c1[2H]]

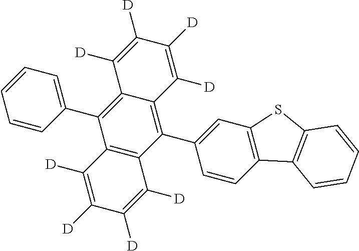 [SMILES: [2H]c1c([2H])c([2H])c2c(-c3ccc4c(c3)sc3ccccc34)c3c([2H])c([2H])c([2H])c([2H])c3c(-c3ccccc3)c2c1[2H]]

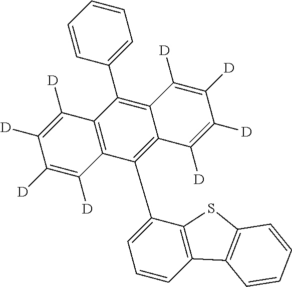 [SMILES: [2H]c1c([2H])c([2H])c2c(-c3cccc4c3sc3ccccc34)c3c([2H])c([2H])c([2H])c([2H])c3c(-c3ccccc3)c2c1[2H]]

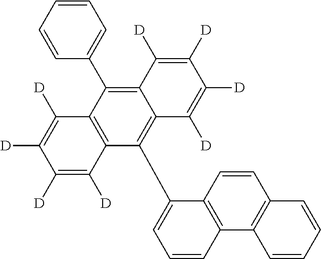 [SMILES: [2H]c1c([2H])c([2H])c2c(-c3cccc4c3ccc3ccccc34)c3c([2H])c([2H])c([2H])c([2H])c3c(-c3ccccc3)c2c1[2H]]

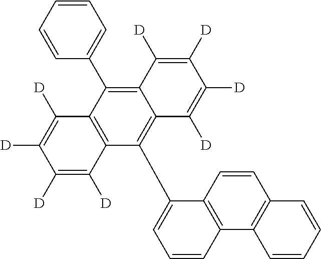 [SMILES: [2H]c1c([2H])c([2H])c2c(-c3cccc4c3ccc3ccccc34)c3c([2H])c([2H])c([2H])c([2H])c3c(-c3ccccc3)c2c1[2H]]

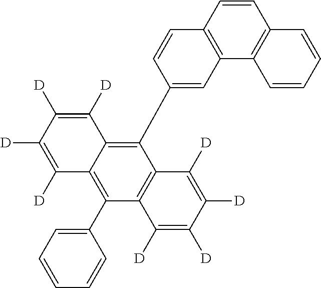 [SMILES: [2H]c1c([2H])c([2H])c2c(-c3ccc4ccc5ccccc5c4c3)c3c([2H])c([2H])c([2H])c([2H])c3c(-c3ccccc3)c2c1[2H]]

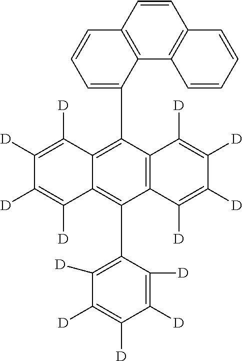 [SMILES: [2H]c1c([2H])c([2H])c(-c2c3c([2H])c([2H])c([2H])c([2H])c3c(-c3cccc4ccc5ccccc5c34)c3c([2H])c([2H])c([2H])c([2H])c23)c([2H])c1[2H]]

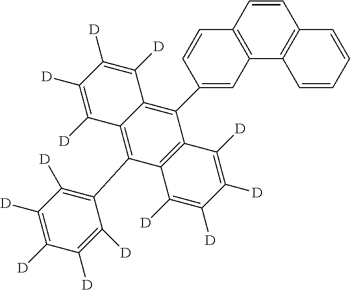 [SMILES: [2H]c1c([2H])c([2H])c(-c2c3c([2H])c([2H])c([2H])c([2H])c3c(-c3ccc4ccc5ccccc5c4c3)c3c([2H])c([2H])c([2H])c([2H])c23)c([2H])c1[2H]]

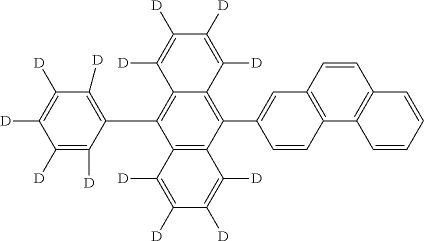 [SMILES: [2H]c1c([2H])c([2H])c(-c2c3c([2H])c([2H])c([2H])c([2H])c3c(-c3ccc4c(ccc5ccccc54)c3)c3c([2H])c([2H])c([2H])c([2H])c23)c([2H])c1[2H]]

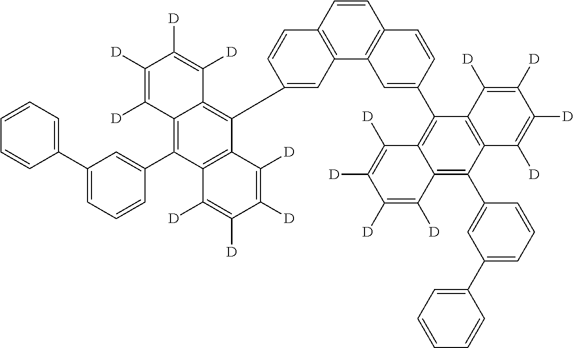 [SMILES: [2H]c1c([2H])c([2H])c2c(-c3ccc4ccc5ccc(-c6c7c([2H])c([2H])c([2H])c([2H])c7c(-c7cccc(-c8ccccc8)c7)c7c([2H])c([2H])c([2H])c([2H])c67)cc5c4c3)c3c([2H])c([2H])c([2H])c([2H])c3c(-c3cccc(-c4ccccc4)c3)c2c1[2H]]

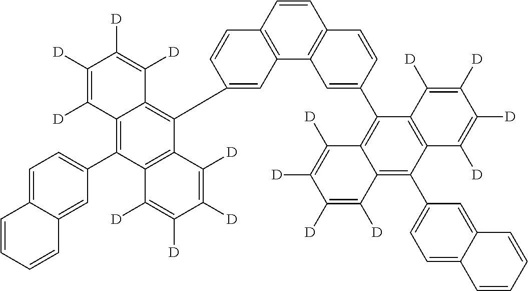 [SMILES: [2H]c1c([2H])c([2H])c2c(-c3ccc4ccc5ccc(-c6c7c([2H])c([2H])c([2H])c([2H])c7c(-c7ccc8ccccc8c7)c7c([2H])c([2H])c([2H])c([2H])c67)cc5c4c3)c3c([2H])c([2H])c([2H])c([2H])c3c(-c3ccc4ccccc4c3)c2c1[2H]]

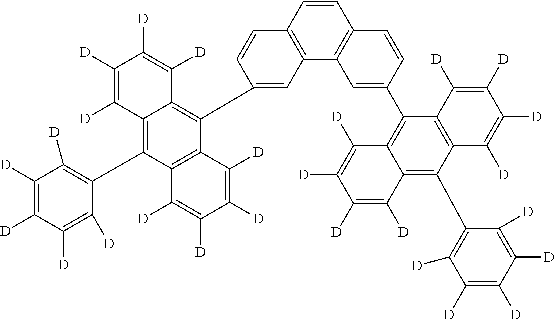 [SMILES: [2H]c1c([2H])c([2H])c(-c2c3c([2H])c([2H])c([2H])c([2H])c3c(-c3ccc4ccc5ccc(-c6c7c([2H])c([2H])c([2H])c([2H])c7c(-c7c([2H])c([2H])c([2H])c([2H])c7[2H])c7c([2H])c([2H])c([2H])c([2H])c67)cc5c4c3)c3c([2H])c([2H])c([2H])c([2H])c23)c([2H])c1[2H]]

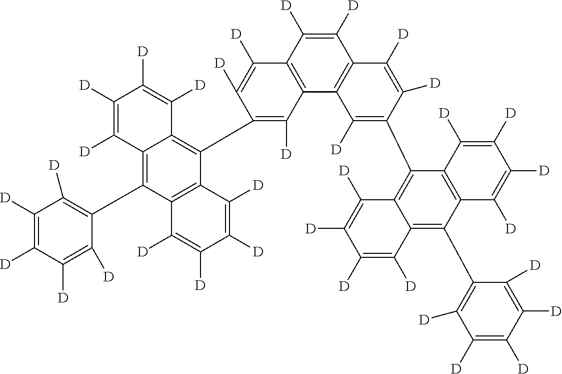 [SMILES: [2H]c1c([2H])c([2H])c(-c2c3c([2H])c([2H])c([2H])c([2H])c3c(-c3c([2H])c([2H])c4c([2H])c([2H])c5c([2H])c([2H])c(-c6c7c([2H])c([2H])c([2H])c([2H])c7c(-c7c([2H])c([2H])c([2H])c([2H])c7[2H])c7c([2H])c([2H])c([2H])c([2H])c67)c([2H])c5c4c3[2H])c3c([2H])c([2H])c([2H])c([2H])c23)c([2H])c1[2H]]

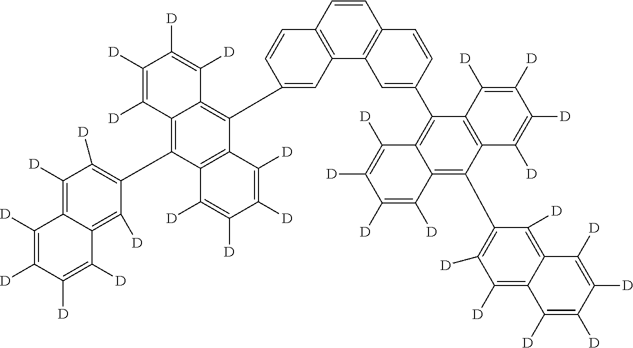 [SMILES: [2H]c1c([2H])c([2H])c2c([2H])c(-c3c4c([2H])c([2H])c([2H])c([2H])c4c(-c4ccc5ccc6ccc(-c7c8c([2H])c([2H])c([2H])c([2H])c8c(-c8c([2H])c([2H])c9c([2H])c([2H])c([2H])c([2H])c9c8[2H])c8c([2H])c([2H])c([2H])c([2H])c78)cc6c5c4)c4c([2H])c([2H])c([2H])c([2H])c34)c([2H])c([2H])c2c1[2H]]

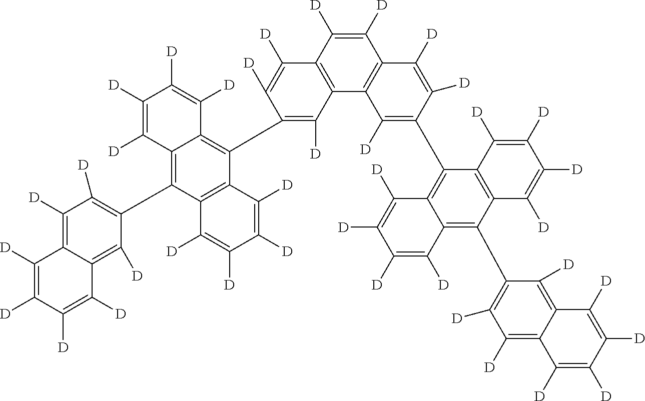 [SMILES: [2H]c1c([2H])c([2H])c2c([2H])c(-c3c4c([2H])c([2H])c([2H])c([2H])c4c(-c4c([2H])c([2H])c5c([2H])c([2H])c6c([2H])c([2H])c(-c7c8c([2H])c([2H])c([2H])c([2H])c8c(-c8c([2H])c([2H])c9c([2H])c([2H])c([2H])c([2H])c9c8[2H])c8c([2H])c([2H])c([2H])c([2H])c78)c([2H])c6c5c4[2H])c4c([2H])c([2H])c([2H])c([2H])c34)c([2H])c([2H])c2c1[2H]]

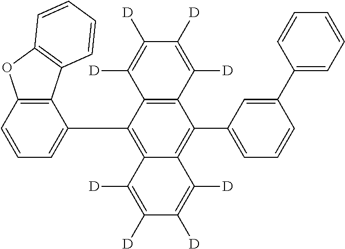 [SMILES: [2H]c1c([2H])c([2H])c2c(-c3cccc4oc5ccccc5c34)c3c([2H])c([2H])c([2H])c([2H])c3c(-c3cccc(-c4ccccc4)c3)c2c1[2H]]

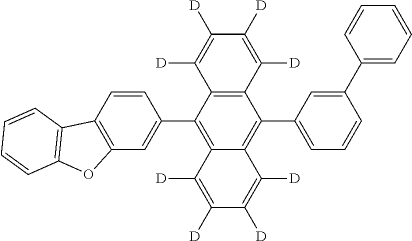 [SMILES: [2H]c1c([2H])c([2H])c2c(-c3ccc4c(c3)oc3ccccc34)c3c([2H])c([2H])c([2H])c([2H])c3c(-c3cccc(-c4ccccc4)c3)c2c1[2H]]

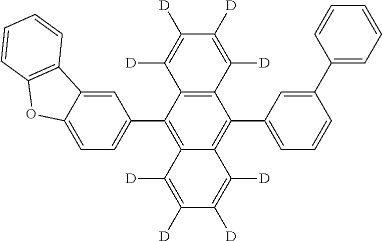 [SMILES: [2H]c1c([2H])c([2H])c2c(-c3ccc4oc5ccccc5c4c3)c3c([2H])c([2H])c([2H])c([2H])c3c(-c3cccc(-c4ccccc4)c3)c2c1[2H]]

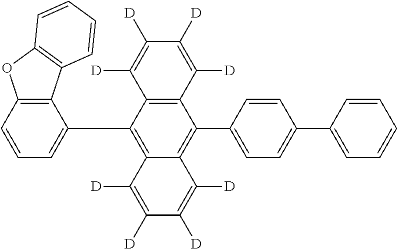 [SMILES: [2H]c1c([2H])c([2H])c2c(-c3cccc4oc5ccccc5c34)c3c([2H])c([2H])c([2H])c([2H])c3c(-c3ccc(-c4ccccc4)cc3)c2c1[2H]]

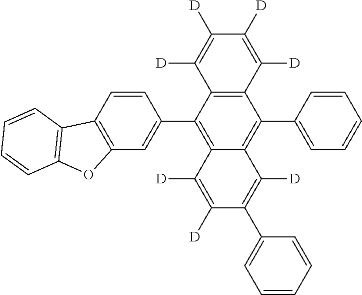 [SMILES: [2H]c1c([2H])c([2H])c2c(-c3ccccc3)c3c([2H])c(-c4ccccc4)c([2H])c([2H])c3c(-c3ccc4c(c3)oc3ccccc34)c2c1[2H]]

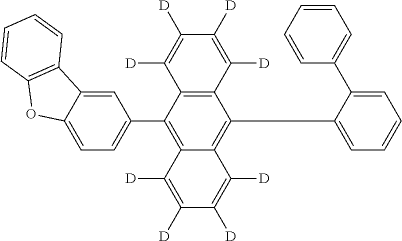 [SMILES: [2H]c1c([2H])c([2H])c2c(-c3ccccc3-c3ccccc3)c3c([2H])c([2H])c([2H])c([2H])c3c(-c3ccc4oc5ccccc5c4c3)c2c1[2H]]

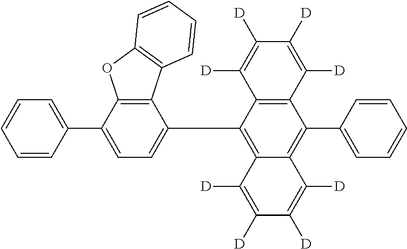 [SMILES: [2H]c1c([2H])c([2H])c2c(-c3ccc(-c4ccccc4)c4oc5ccccc5c34)c3c([2H])c([2H])c([2H])c([2H])c3c(-c3ccccc3)c2c1[2H]]

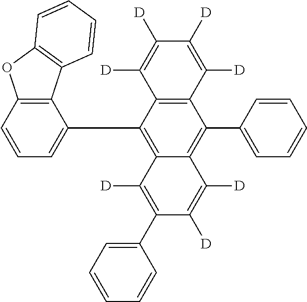 [SMILES: [2H]c1c([2H])c([2H])c2c(-c3cccc4oc5ccccc5c34)c3c([2H])c(-c4ccccc4)c([2H])c([2H])c3c(-c3ccccc3)c2c1[2H]]

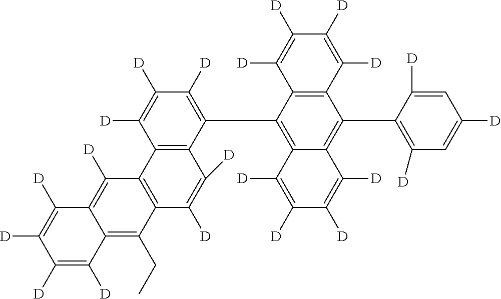 [SMILES: [2H]c1cc([2H])c(-c2c3c([2H])c([2H])c([2H])c([2H])c3c(-c3c([2H])c([2H])c([2H])c4c3c([2H])c([2H])c3c(CC)c5c([2H])c([2H])c([2H])c([2H])c5c([2H])c34)c3c([2H])c([2H])c([2H])c([2H])c23)c([2H])c1]

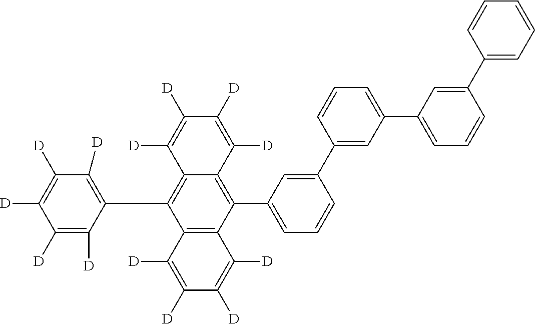 [SMILES: [2H]c1c([2H])c([2H])c(-c2c3c([2H])c([2H])c([2H])c([2H])c3c(-c3cccc(-c4cccc(-c5cccc(-c6ccccc6)c5)c4)c3)c3c([2H])c([2H])c([2H])c([2H])c23)c([2H])c1[2H]]

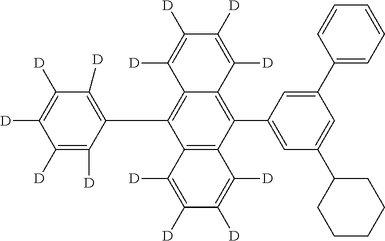 [SMILES: [2H]c1c([2H])c([2H])c(-c2c3c([2H])c([2H])c([2H])c([2H])c3c(-c3cc(-c4ccccc4)cc(C4CCCCC4)c3)c3c([2H])c([2H])c([2H])c([2H])c23)c([2H])c1[2H]]

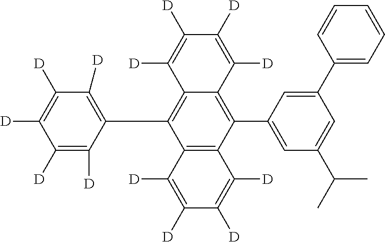 [SMILES: [2H]c1c([2H])c([2H])c(-c2c3c([2H])c([2H])c([2H])c([2H])c3c(-c3cc(-c4ccccc4)cc(C(C)C)c3)c3c([2H])c([2H])c([2H])c([2H])c23)c([2H])c1[2H]]

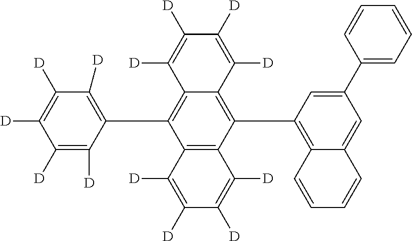 [SMILES: [2H]c1c([2H])c([2H])c(-c2c3c([2H])c([2H])c([2H])c([2H])c3c(-c3cc(-c4ccccc4)cc4ccccc34)c3c([2H])c([2H])c([2H])c([2H])c23)c([2H])c1[2H]]

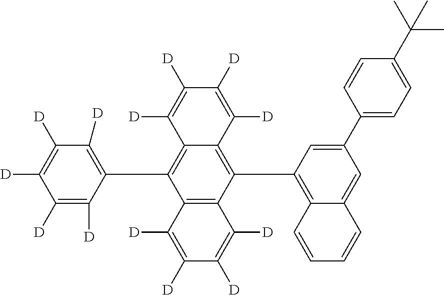 [SMILES: [2H]c1c([2H])c([2H])c(-c2c3c([2H])c([2H])c([2H])c([2H])c3c(-c3cc(-c4ccc(C(C)(C)C)cc4)cc4ccccc34)c3c([2H])c([2H])c([2H])c([2H])c23)c([2H])c1[2H]]

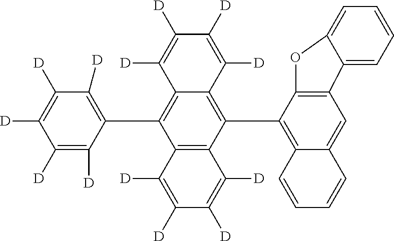 [SMILES: [2H]c1c([2H])c([2H])c(-c2c3c([2H])c([2H])c([2H])c([2H])c3c(-c3c4ccccc4cc4c3oc3ccccc34)c3c([2H])c([2H])c([2H])c([2H])c23)c([2H])c1[2H]]

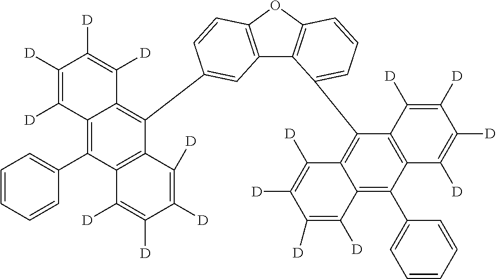 [SMILES: [2H]c1c([2H])c([2H])c2c(-c3ccc4oc5cccc(-c6c7c([2H])c([2H])c([2H])c([2H])c7c(-c7ccccc7)c7c([2H])c([2H])c([2H])c([2H])c67)c5c4c3)c3c([2H])c([2H])c([2H])c([2H])c3c(-c3ccccc3)c2c1[2H]]

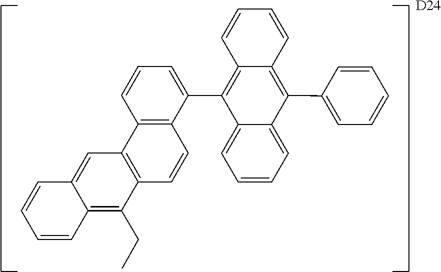

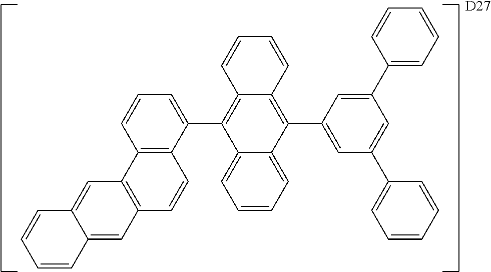

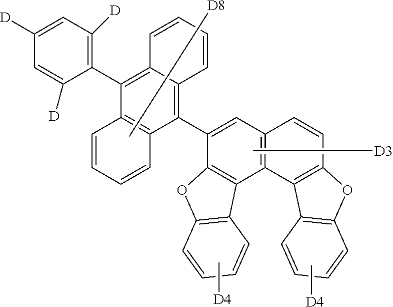

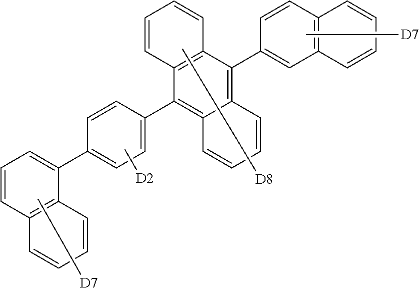

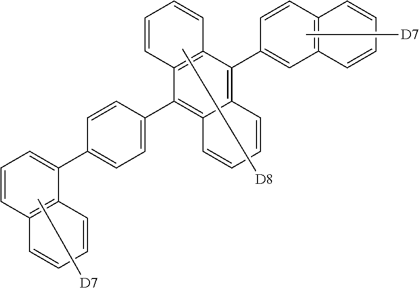

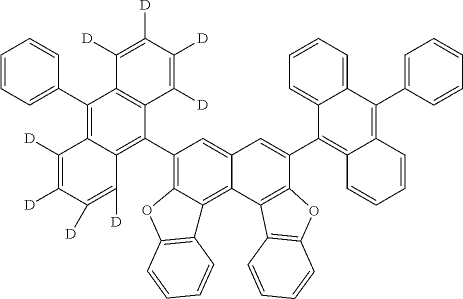 [SMILES: [2H]c1c([2H])c([2H])c2c(-c3cc4cc(-c5c6ccccc6c(-c6ccccc6)c6ccccc56)c5oc6ccccc6c5c4c4c3oc3ccccc34)c3c([2H])c([2H])c([2H])c([2H])c3c(-c3ccccc3)c2c1[2H]]

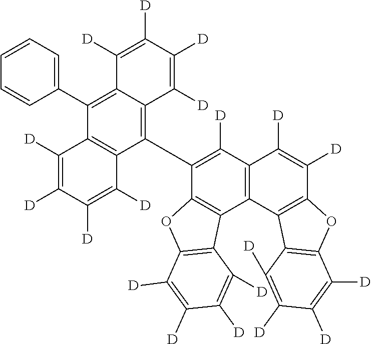 [SMILES: [2H]c1c([2H])c([2H])c2c(oc3c([2H])c([2H])c4c([2H])c(-c5c6c([2H])c([2H])c([2H])c([2H])c6c(-c6ccccc6)c6c([2H])c([2H])c([2H])c([2H])c56)c5oc6c([2H])c([2H])c([2H])c([2H])c6c5c4c32)c1[2H]]

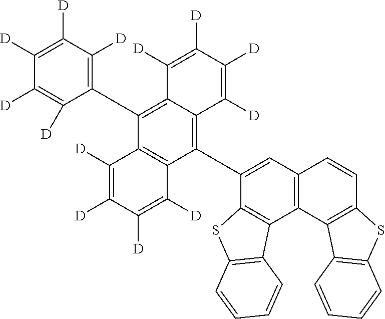 [SMILES: [2H]c1c([2H])c([2H])c(-c2c3c([2H])c([2H])c([2H])c([2H])c3c(-c3cc4ccc5sc6ccccc6c5c4c4c3sc3ccccc34)c3c([2H])c([2H])c([2H])c([2H])c23)c([2H])c1[2H]]

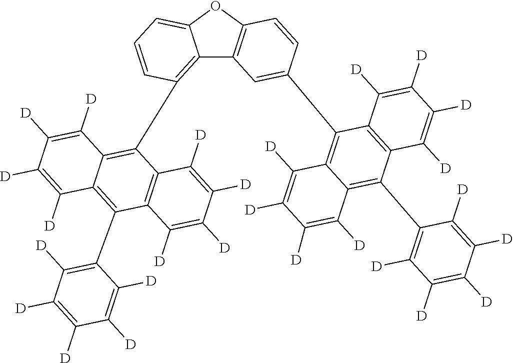 [SMILES: [2H]c1c([2H])c([2H])c(-c2c3c([2H])c([2H])c([2H])c([2H])c3c(-c3ccc4oc5cccc(-c6c7c([2H])c([2H])c([2H])c([2H])c7c(-c7c([2H])c([2H])c([2H])c([2H])c7[2H])c7c([2H])c([2H])c([2H])c([2H])c67)c5c4c3)c3c([2H])c([2H])c([2H])c([2H])c23)c([2H])c1[2H]]

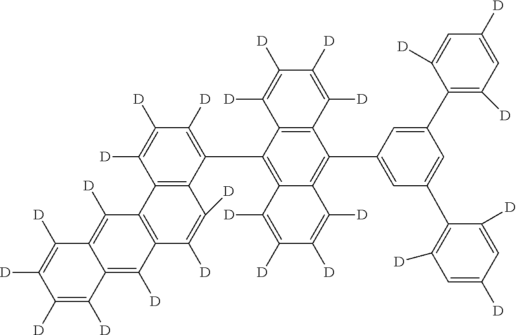 [SMILES: [2H]c1cc([2H])c(-c2cc(-c3c([2H])cc([2H])cc3[2H])cc(-c3c4c([2H])c([2H])c([2H])c([2H])c4c(-c4c([2H])c([2H])c([2H])c5c4c([2H])c([2H])c4c([2H])c6c([2H])c([2H])c([2H])c([2H])c6c([2H])c45)c4c([2H])c([2H])c([2H])c([2H])c34)c2)c([2H])c1]

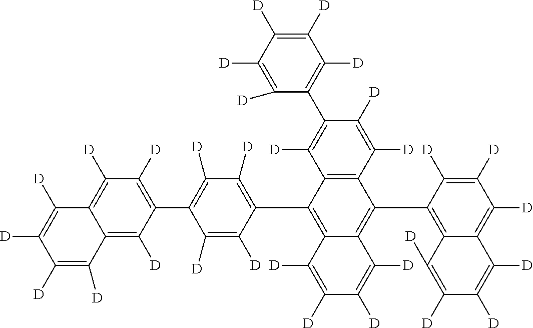 [SMILES: [2H]c1c([2H])c([2H])c(-c2c([2H])c([2H])c3c(-c4c([2H])c([2H])c([2H])c5c([2H])c([2H])c([2H])c([2H])c45)c4c([2H])c([2H])c([2H])c([2H])c4c(-c4c([2H])c([2H])c(-c5c([2H])c([2H])c6c([2H])c([2H])c([2H])c([2H])c6c5[2H])c([2H])c4[2H])c3c2[2H])c([2H])c1[2H]]

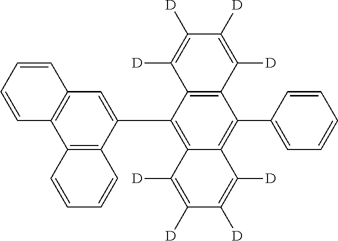 [SMILES: [2H]c1c([2H])c([2H])c2c(-c3cc4ccccc4c4ccccc34)c3c([2H])c([2H])c([2H])c([2H])c3c(-c3ccccc3)c2c1[2H]]

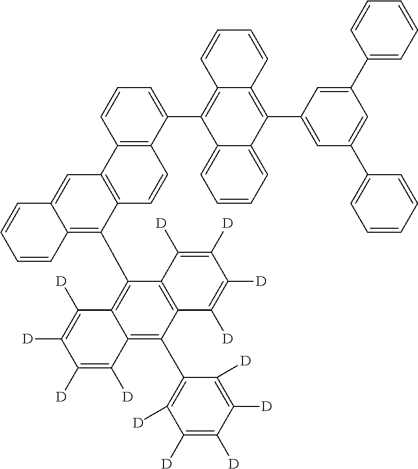 [SMILES: [2H]c1c([2H])c([2H])c(-c2c3c([2H])c([2H])c([2H])c([2H])c3c(-c3c4ccccc4cc4c3ccc3c(-c5c6ccccc6c(-c6cc(-c7ccccc7)cc(-c7ccccc7)c6)c6ccccc56)cccc34)c3c([2H])c([2H])c([2H])c([2H])c23)c([2H])c1[2H]]

In accordance with a preferred embodiment, the group Ant2 is represented by Formula II-1, where n is equal to 0.

In accordance with another preferred embodiment, the group Ant2 is represented by Formula II-1, where n is an integer from 1 to 8, preferably, from 4 to 8.

Still in accordance with a preferred embodiment, the group Ant2 is represented by Formula II-1, where n is equal to 8.

More preferably, Ant2 is represented by formula (II-1):

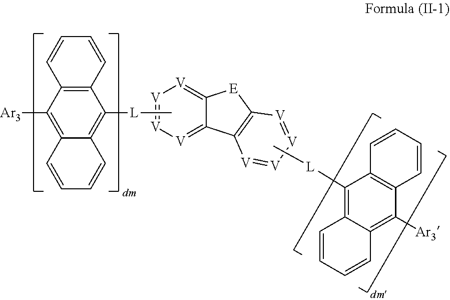

Where Ar₃ and n have the same meaning as above; and where the anthracene depicted in Formula (II-1) might be substituted by a radical R′ at any free position;
E is a divalent bridge selected from —C═C—, —C(R⁰)₂—, Si(R⁰)₂—, —O—, —S—, —C(═O)—, —S(═O)—, —SO₂—, —BR⁰—, —N(R⁰)— or —P(R⁰)—, preferably C═C—, —C(R⁰)₂—, —O—, —S—; and where R⁰ stands on each occurrence, identically or differently, for H, F, CN, a straight-chain alkyl group having 1 to 40 C atoms or branched or cyclic alkyl group having 3 to 40 atoms, each of which may be substituted by one or more radicals R, an aromatic or heteroaromatic ring system having 5 to 60 aromatic ring atoms, which may in each case be substituted by one or more radicals R; where two adjacent substituents R⁰ may form a mono- or polycyclic, aliphatic ring system or aromatic ring system, which may be substituted by one or more radicals R;
V stands on each occurrence, identically or differently, for C—R or N; with the proviso that V stands for C when it is bonded to an adjacent group;
L stands on each occurrence, identically or differently for a single bond or for a divalent group selected from aryl and heteroaryl groups having 5 to 18 aromatic ring atoms
Ar₃′ stands for an aromatic or heteroaromatic ring system having 5 to 60 aromatic ring atoms, which may in each case also be substituted by one or more radicals R;
m and m′ are independently an integer selected from 0 to 8.

Suitable examples of compounds of Ant2 are depicted in the table below:

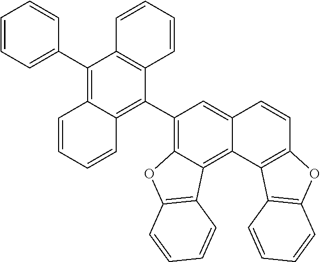 [SMILES: c1ccc(-c2c3ccccc3c(-c3cc4ccc5oc6ccccc6c5c4c4c3oc3ccccc34)c3ccccc23)cc1]

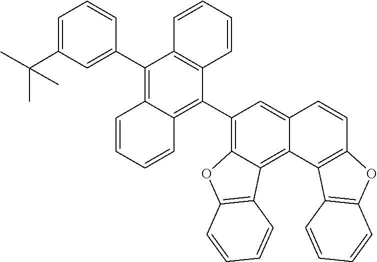 [SMILES: CC(C)(C)c1cccc(-c2c3ccccc3c(-c3cc4ccc5oc6ccccc6c5c4c4c3oc3ccccc34)c3ccccc23)c1]

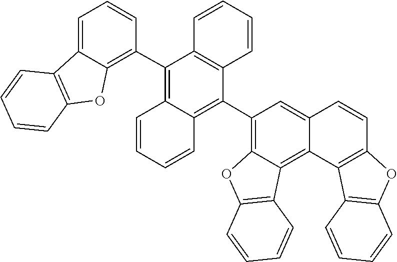 [SMILES: c1ccc2c(c1)oc1c(-c3c4ccccc4c(-c4cc5ccc6oc7ccccc7c6c5c5c4oc4ccccc45)c4ccccc34)cccc12]

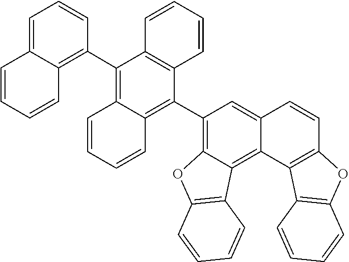 [SMILES: c1ccc2c(-c3c4ccccc4c(-c4cc5ccc6oc7ccccc7c6c5c5c4oc4ccccc45)c4ccccc34)cccc2c1]

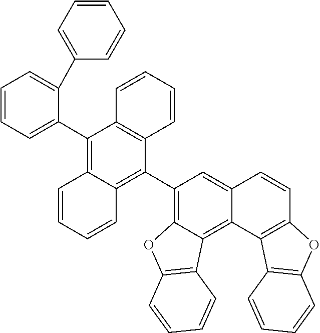 [SMILES: c1ccc(-c2ccccc2-c2c3ccccc3c(-c3cc4ccc5oc6ccccc6c5c4c4c3oc3ccccc34)c3ccccc23)cc1]

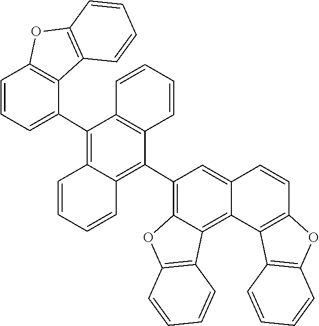 [SMILES: c1ccc2c(c1)oc1cccc(-c3c4ccccc4c(-c4cc5ccc6oc7ccccc7c6c5c5c4oc4ccccc45)c4ccccc34)c12]

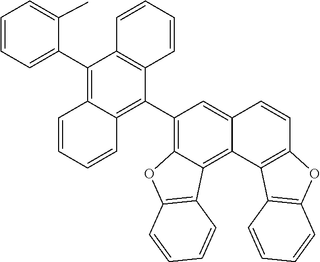 [SMILES: Cc1ccccc1-c1c2ccccc2c(-c2cc3ccc4oc5ccccc5c4c3c3c2oc2ccccc23)c2ccccc12]

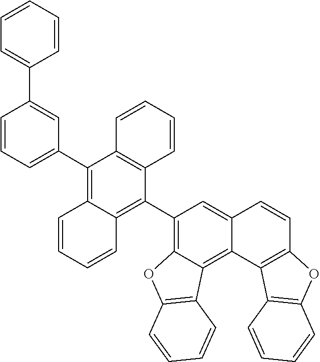 [SMILES: c1ccc(-c2cccc(-c3c4ccccc4c(-c4cc5ccc6oc7ccccc7c6c5c5c4oc4ccccc45)c4ccccc34)c2)cc1]

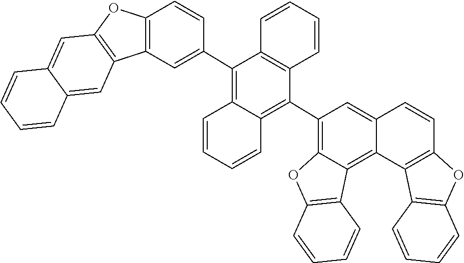 [SMILES: c1ccc2cc3c(cc2c1)oc1ccc(-c2c4ccccc4c(-c4cc5ccc6oc7ccccc7c6c5c5c4oc4ccccc45)c4ccccc24)cc13]

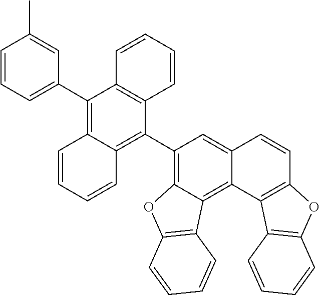 [SMILES: Cc1cccc(-c2c3ccccc3c(-c3cc4ccc5oc6ccccc6c5c4c4c3oc3ccccc34)c3ccccc23)c1]

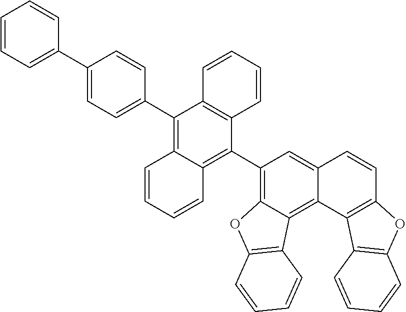 [SMILES: c1ccc(-c2ccc(-c3c4ccccc4c(-c4cc5ccc6oc7ccccc7c6c5c5c4oc4ccccc45)c4ccccc34)cc2)cc1]

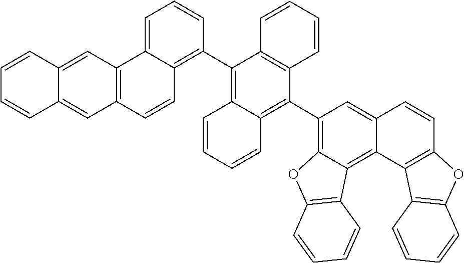 [SMILES: c1ccc2cc3c(ccc4c(-c5c6ccccc6c(-c6cc7ccc8oc9ccccc9c8c7c7c6oc6ccccc67)c6ccccc56)cccc43)cc2c1]

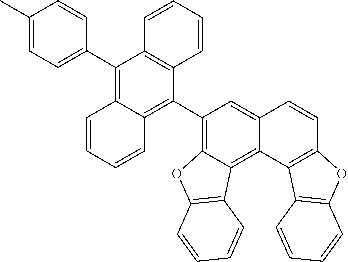 [SMILES: Cc1ccc(-c2c3ccccc3c(-c3cc4ccc5oc6ccccc6c5c4c4c3oc3ccccc34)c3ccccc23)cc1]

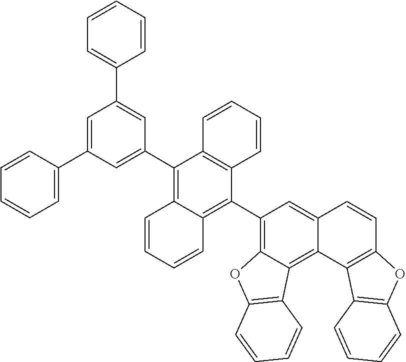 [SMILES: c1ccc(-c2cc(-c3ccccc3)cc(-c3c4ccccc4c(-c4cc5ccc6oc7ccccc7c6c5c5c4oc4ccccc45)c4ccccc34)c2)cc1]

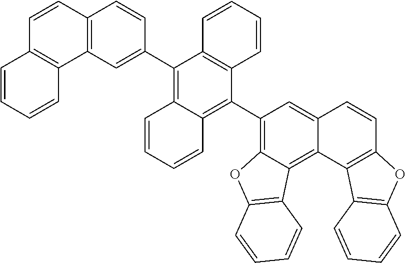 [SMILES: c1ccc2c(c1)ccc1ccc(-c3c4ccccc4c(-c4cc5ccc6oc7ccccc7c6c5c5c4oc4ccccc45)c4ccccc34)cc12]

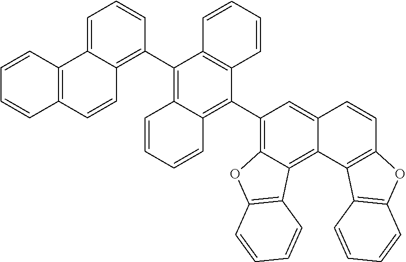 [SMILES: c1ccc2c(c1)ccc1c(-c3c4ccccc4c(-c4cc5ccc6oc7ccccc7c6c5c5c4oc4ccccc45)c4ccccc34)cccc12]

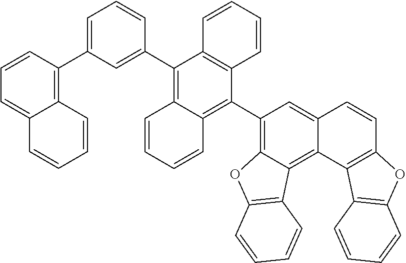 [SMILES: c1cc(-c2cccc3ccccc23)cc(-c2c3ccccc3c(-c3cc4ccc5oc6ccccc6c5c4c4c3oc3ccccc34)c3ccccc23)c1]

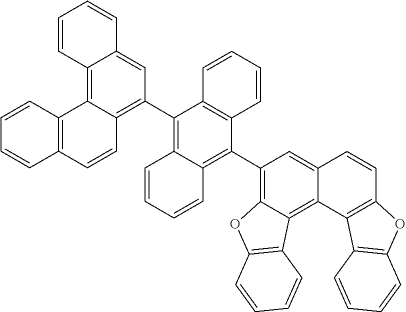 [SMILES: c1ccc2c(c1)ccc1c(-c3c4ccccc4c(-c4cc5ccc6oc7ccccc7c6c5c5c4oc4ccccc45)c4ccccc34)cc3ccccc3c12]

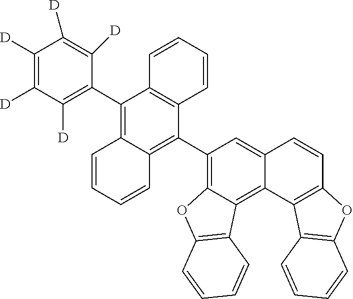 [SMILES: [2H]c1c([2H])c([2H])c(-c2c3ccccc3c(-c3cc4ccc5oc6ccccc6c5c4c4c3oc3ccccc34)c3ccccc23)c([2H])c1[2H]]

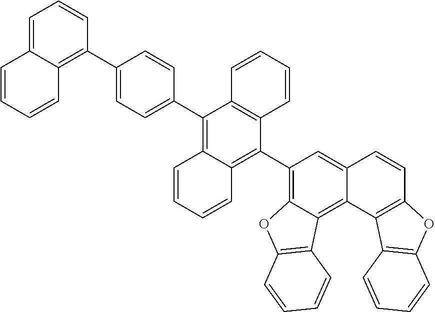 [SMILES: c1ccc2c(-c3ccc(-c4c5ccccc5c(-c5cc6ccc7oc8ccccc8c7c6c6c5oc5ccccc56)c5ccccc45)cc3)cccc2c1]

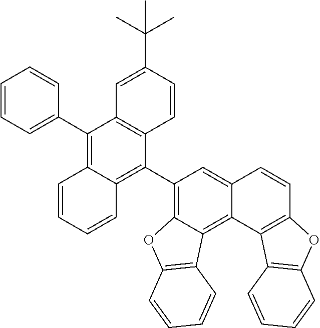 [SMILES: CC(C)(C)c1ccc2c(-c3cc4ccc5oc6ccccc6c5c4c4c3oc3ccccc34)c3ccccc3c(-c3ccccc3)c2c1]

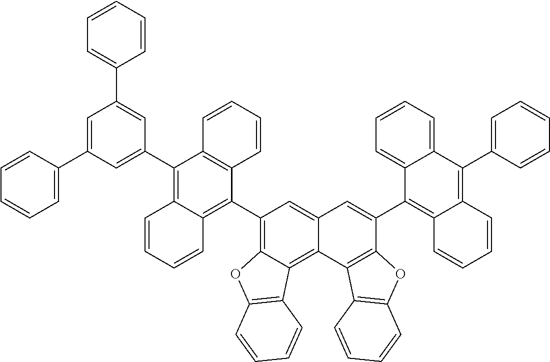 [SMILES: c1ccc(-c2cc(-c3ccccc3)cc(-c3c4ccccc4c(-c4cc5cc(-c6c7ccccc7c(-c7ccccc7)c7ccccc67)c6oc7ccccc7c6c5c5c4oc4ccccc45)c4ccccc34)c2)cc1]

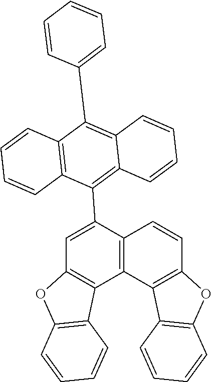 [SMILES: c1ccc(-c2c3ccccc3c(-c3cc4oc5ccccc5c4c4c3ccc3oc5ccccc5c34)c3ccccc23)cc1]

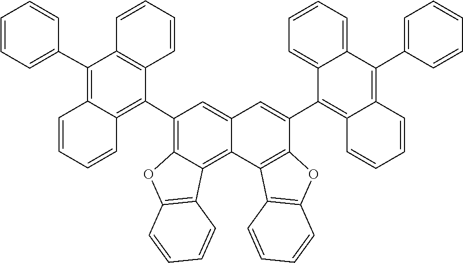 [SMILES: c1ccc(-c2c3ccccc3c(-c3cc4cc(-c5c6ccccc6c(-c6ccccc6)c6ccccc56)c5oc6ccccc6c5c4c4c3oc3ccccc34)c3ccccc23)cc1]

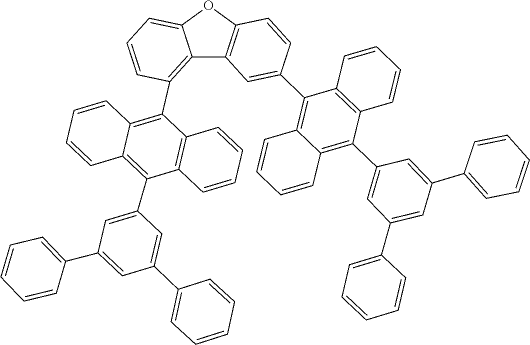 [SMILES: c1ccc(-c2cc(-c3ccccc3)cc(-c3c4ccccc4c(-c4ccc5oc6cccc(-c7c8ccccc8c(-c8cc(-c9ccccc9)cc(-c9ccccc9)c8)c8ccccc78)c6c5c4)c4ccccc34)c2)cc1]

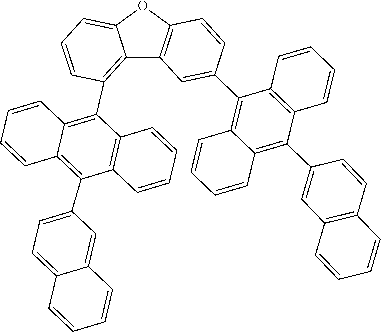 [SMILES: c1ccc2cc(-c3c4ccccc4c(-c4ccc5oc6cccc(-c7c8ccccc8c(-c8ccc9ccccc9c8)c8ccccc78)c6c5c4)c4ccccc34)ccc2c1]

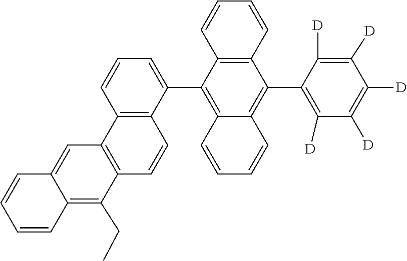 [SMILES: [2H]c1c([2H])c([2H])c(-c2c3ccccc3c(-c3cccc4c3ccc3c(CC)c5ccccc5cc34)c3ccccc23)c([2H])c1[2H]]

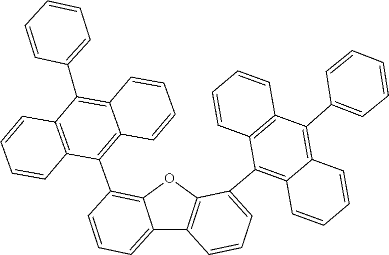 [SMILES: c1ccc(-c2c3ccccc3c(-c3cccc4c3oc3c(-c5c6ccccc6c(-c6ccccc6)c6ccccc56)cccc34)c3ccccc23)cc1]

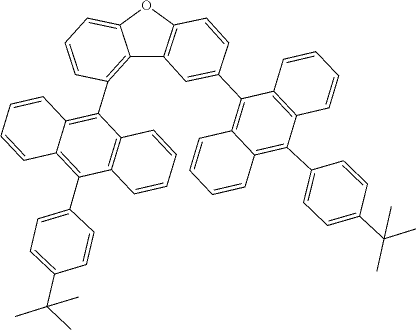 [SMILES: CC(C)(C)c1ccc(-c2c3ccccc3c(-c3ccc4oc5cccc(-c6c7ccccc7c(-c7ccc(C(C)(C)C)cc7)c7ccccc67)c5c4c3)c3ccccc23)cc1]

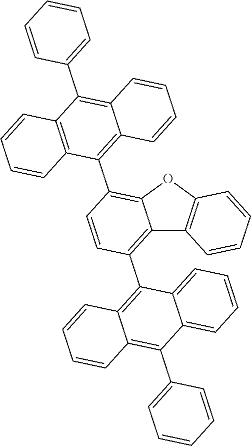 [SMILES: c1ccc(-c2c3ccccc3c(-c3ccc(-c4c5ccccc5c(-c5ccccc5)c5ccccc45)c4c3oc3ccccc34)c3ccccc23)cc1]

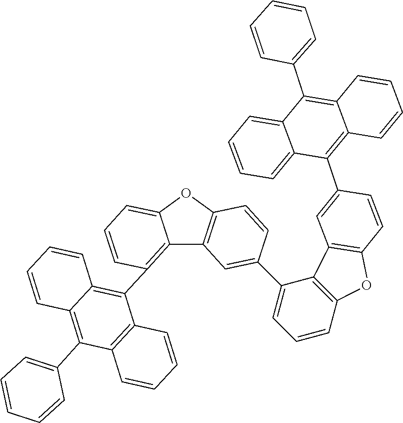 [SMILES: c1ccc(-c2c3ccccc3c(-c3ccc4oc5cccc(-c6ccc7oc8cccc(-c9c%10ccccc%10c(-c%10ccccc%10)c%10ccccc9%10)c8c7c6)c5c4c3)c3ccccc23)cc1]

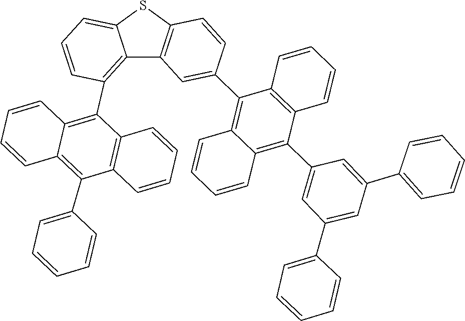 [SMILES: c1ccc(-c2cc(-c3ccccc3)cc(-c3c4ccccc4c(-c4ccc5sc6cccc(-c7c8ccccc8c(-c8ccccc8)c8ccccc78)c6c5c4)c4ccccc34)c2)cc1]

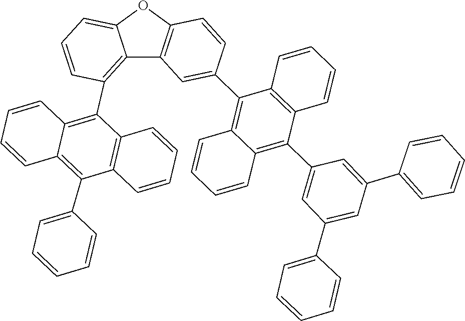 [SMILES: c1ccc(-c2cc(-c3ccccc3)cc(-c3c4ccccc4c(-c4ccc5oc6cccc(-c7c8ccccc8c(-c8ccccc8)c8ccccc78)c6c5c4)c4ccccc34)c2)cc1]

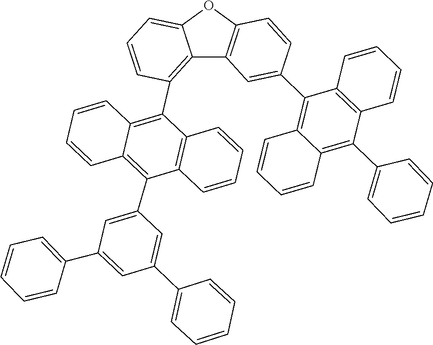 [SMILES: c1ccc(-c2cc(-c3ccccc3)cc(-c3c4ccccc4c(-c4cccc5oc6ccc(-c7c8ccccc8c(-c8ccccc8)c8ccccc78)cc6c45)c4ccccc34)c2)cc1]

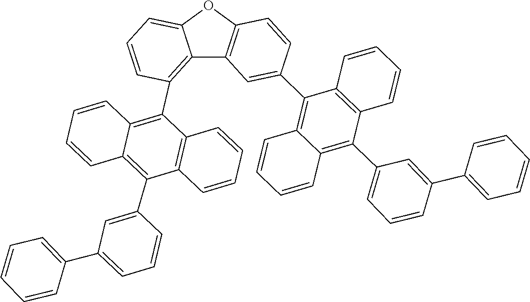 [SMILES: c1ccc(-c2cccc(-c3c4ccccc4c(-c4ccc5oc6cccc(-c7c8ccccc8c(-c8cccc(-c9ccccc9)c8)c8ccccc78)c6c5c4)c4ccccc34)c2)cc1]

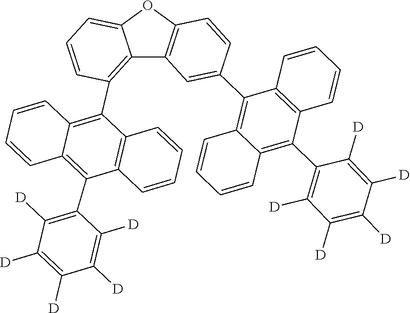 [SMILES: [2H]c1c([2H])c([2H])c(-c2c3ccccc3c(-c3ccc4oc5cccc(-c6c7ccccc7c(-c7c([2H])c([2H])c([2H])c([2H])c7[2H])c7ccccc67)c5c4c3)c3ccccc23)c([2H])c1[2H]]

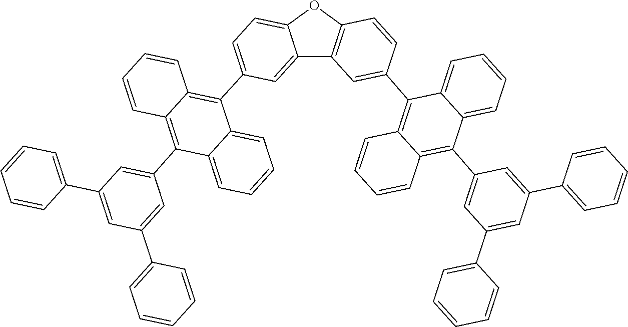 [SMILES: c1ccc(-c2cc(-c3ccccc3)cc(-c3c4ccccc4c(-c4ccc5oc6ccc(-c7c8ccccc8c(-c8cc(-c9ccccc9)cc(-c9ccccc9)c8)c8ccccc78)cc6c5c4)c4ccccc34)c2)cc1]

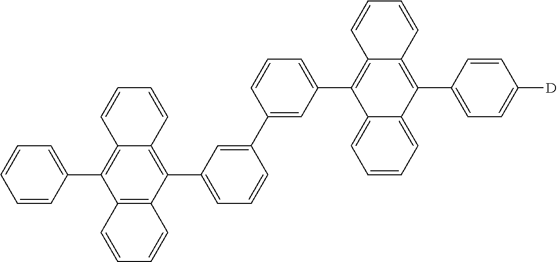 [SMILES: [2H]c1ccc(-c2c3ccccc3c(-c3cccc(-c4cccc(-c5c6ccccc6c(-c6ccccc6)c6ccccc56)c4)c3)c3ccccc23)cc1]

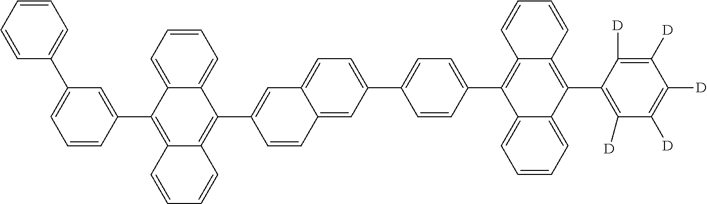 [SMILES: [2H]c1c([2H])c([2H])c(-c2c3ccccc3c(-c3ccc(-c4ccc5cc(-c6c7ccccc7c(-c7cccc(-c8ccccc8)c7)c7ccccc67)ccc5c4)cc3)c3ccccc23)c([2H])c1[2H]]

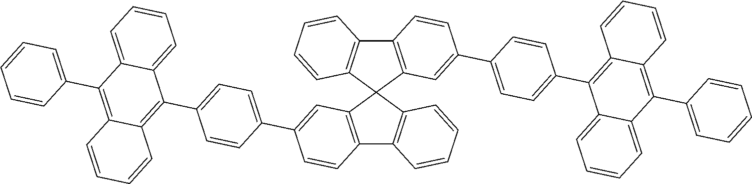 [SMILES: c1ccc(-c2c3ccccc3c(-c3ccc(-c4ccc5c(c4)C4(c6ccccc6-5)c5ccccc5-c5ccc(-c6ccc(-c7c8ccccc8c(-c8ccccc8)c8ccccc78)cc6)cc54)cc3)c3ccccc23)cc1]

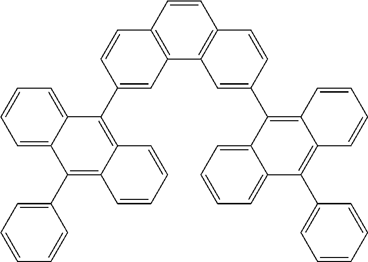 [SMILES: c1ccc(-c2c3ccccc3c(-c3ccc4ccc5ccc(-c6c7ccccc7c(-c7ccccc7)c7ccccc67)cc5c4c3)c3ccccc23)cc1]

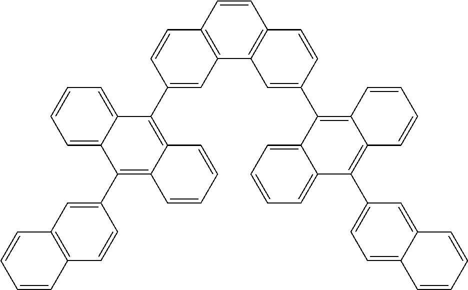 [SMILES: c1ccc2cc(-c3c4ccccc4c(-c4ccc5ccc6ccc(-c7c8ccccc8c(-c8ccc9ccccc9c8)c8ccccc78)cc6c5c4)c4ccccc34)ccc2c1]

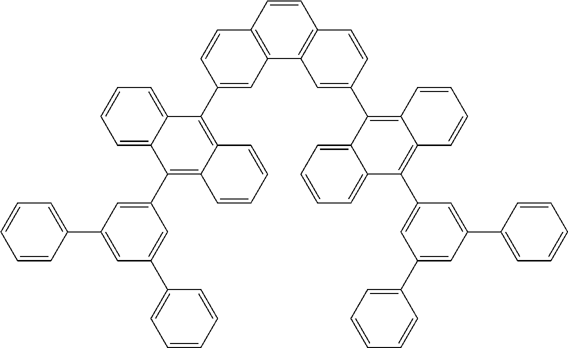 [SMILES: c1ccc(-c2cc(-c3ccccc3)cc(-c3c4ccccc4c(-c4ccc5ccc6ccc(-c7c8ccccc8c(-c8cc(-c9ccccc9)cc(-c9ccccc9)c8)c8ccccc78)cc6c5c4)c4ccccc34)c2)cc1]

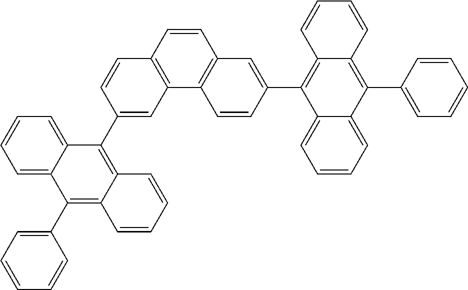 [SMILES: c1ccc(-c2c3ccccc3c(-c3ccc4c(ccc5ccc(-c6c7ccccc7c(-c7ccccc7)c7ccccc67)cc54)c3)c3ccccc23)cc1]

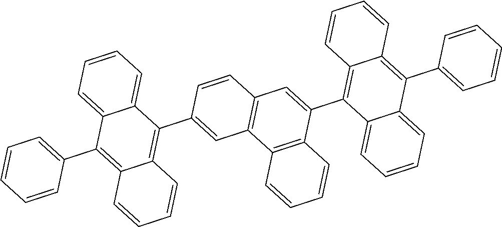 [SMILES: c1ccc(-c2c3ccccc3c(-c3ccc4cc(-c5c6ccccc6c(-c6ccccc6)c6ccccc56)c5ccccc5c4c3)c3ccccc23)cc1]

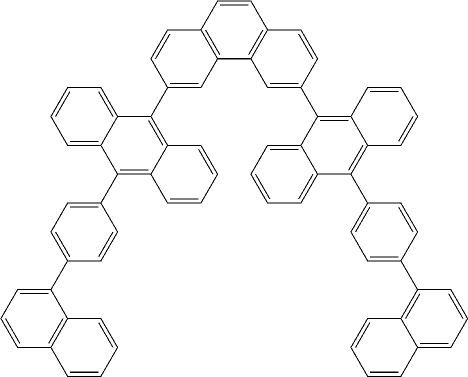 [SMILES: c1ccc2c(-c3ccc(-c4c5ccccc5c(-c5ccc6ccc7ccc(-c8c9ccccc9c(-c9ccc(-c%10cccc%11ccccc%10%11)cc9)c9ccccc89)cc7c6c5)c5ccccc45)cc3)cccc2c1]

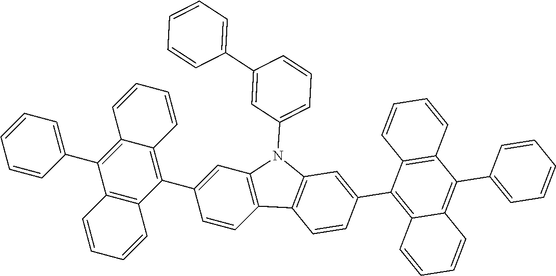 [SMILES: c1ccc(-c2cccc(-n3c4cc(-c5c6ccccc6c(-c6ccccc6)c6ccccc56)ccc4c4ccc(-c5c6ccccc6c(-c6ccccc6)c6ccccc56)cc43)c2)cc1]

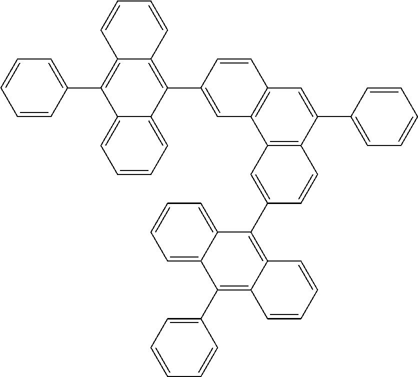 [SMILES: c1ccc(-c2c3ccccc3c(-c3ccc4cc(-c5ccccc5)c5ccc(-c6c7ccccc7c(-c7ccccc7)c7ccccc67)cc5c4c3)c3ccccc23)cc1]

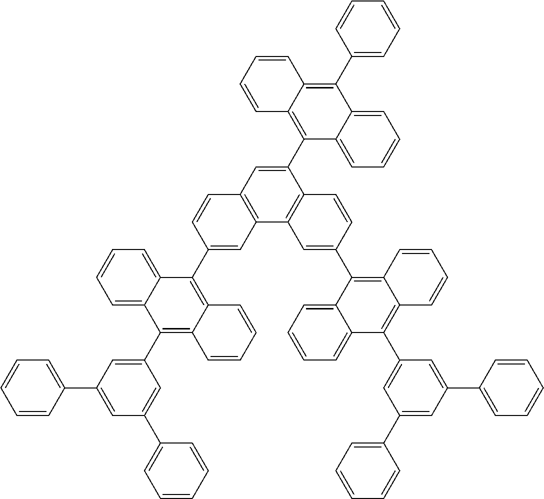 [SMILES: c1ccc(-c2cc(-c3ccccc3)cc(-c3c4ccccc4c(-c4ccc5cc(-c6c7ccccc7c(-c7ccccc7)c7ccccc67)c6ccc(-c7c8ccccc8c(-c8cc(-c9ccccc9)cc(-c9ccccc9)c8)c8ccccc78)cc6c5c4)c4ccccc34)c2)cc1]

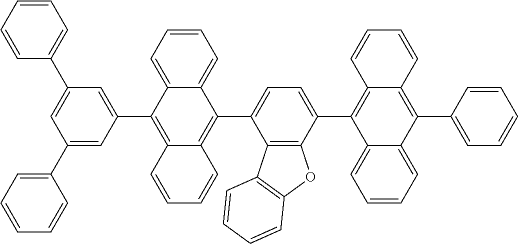 [SMILES: c1ccc(-c2cc(-c3ccccc3)cc(-c3c4ccccc4c(-c4ccc(-c5c6ccccc6c(-c6ccccc6)c6ccccc56)c5oc6ccccc6c45)c4ccccc34)c2)cc1]

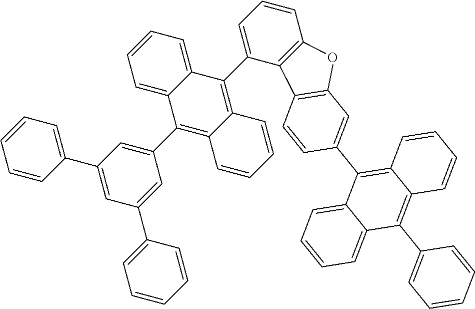 [SMILES: c1ccc(-c2cc(-c3ccccc3)cc(-c3c4ccccc4c(-c4cccc5oc6cc(-c7c8ccccc8c(-c8ccccc8)c8ccccc78)ccc6c45)c4ccccc34)c2)cc1]

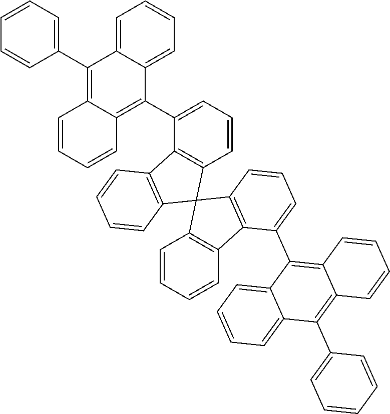 [SMILES: c1ccc(-c2c3ccccc3c(-c3cccc4c3-c3ccccc3C43c4ccccc4-c4c(-c5c6ccccc6c(-c6ccccc6)c6ccccc56)cccc43)c3ccccc23)cc1]

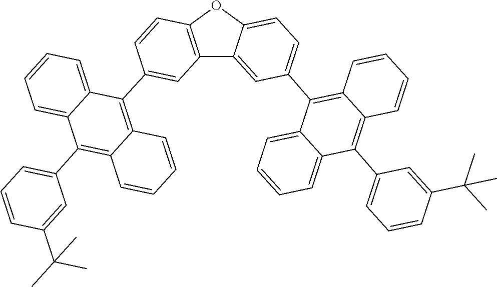 [SMILES: CC(C)(C)c1cccc(-c2c3ccccc3c(-c3ccc4oc5ccc(-c6c7ccccc7c(-c7cccc(C(C)(C)C)c7)c7ccccc67)cc5c4c3)c3ccccc23)c1]

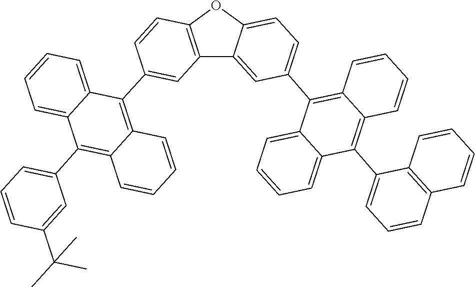 [SMILES: CC(C)(C)c1cccc(-c2c3ccccc3c(-c3ccc4oc5ccc(-c6c7ccccc7c(-c7cccc8ccccc78)c7ccccc67)cc5c4c3)c3ccccc23)c1]

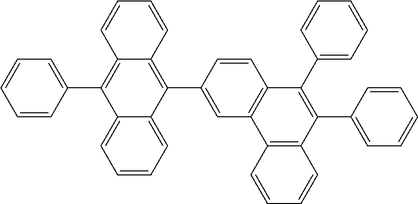 [SMILES: c1ccc(-c2c3ccccc3c(-c3ccc4c(-c5ccccc5)c(-c5ccccc5)c5ccccc5c4c3)c3ccccc23)cc1]

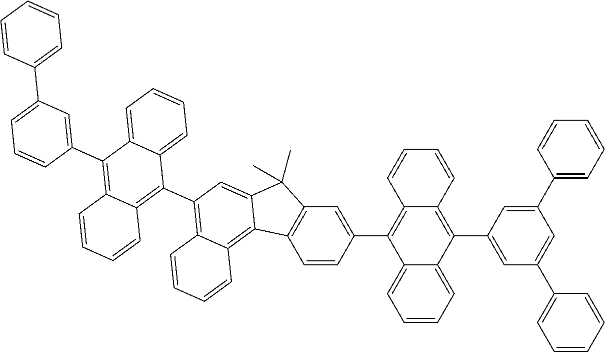 [SMILES: CC1(C)c2cc(-c3c4ccccc4c(-c4cc(-c5ccccc5)cc(-c5ccccc5)c4)c4ccccc34)ccc2-c2c1cc(-c1c3ccccc3c(-c3cccc(-c4ccccc4)c3)c3ccccc13)c1ccccc21]

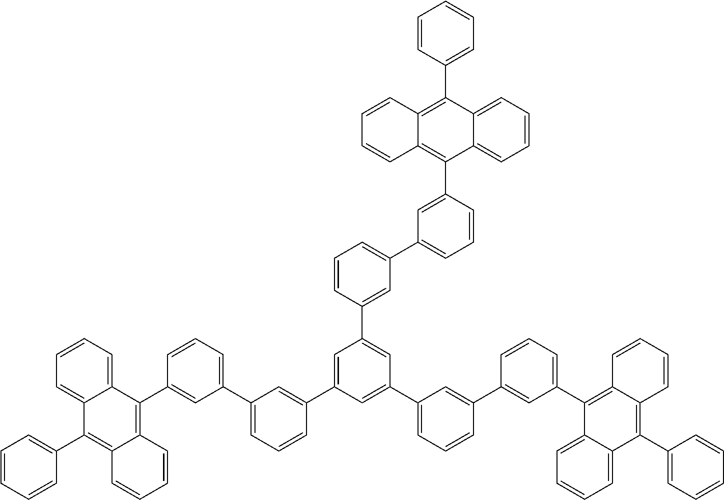 [SMILES: c1ccc(-c2c3ccccc3c(-c3cccc(-c4cccc(-c5cc(-c6cccc(-c7cccc(-c8c9ccccc9c(-c9ccccc9)c9ccccc89)c7)c6)cc(-c6cccc(-c7cccc(-c8c9ccccc9c(-c9ccccc9)c9ccccc89)c7)c6)c5)c4)c3)c3ccccc23)cc1]

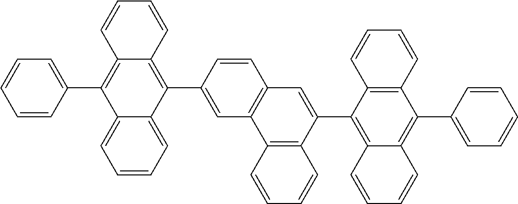 [SMILES: c1ccc(-c2c3ccccc3c(-c3ccc4cc(-c5c6ccccc6c(-c6ccccc6)c6ccccc56)c5ccccc5c4c3)c3ccccc23)cc1]

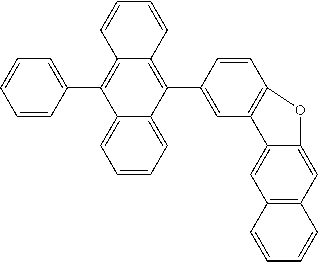 [SMILES: c1ccc(-c2c3ccccc3c(-c3ccc4oc5cc6ccccc6cc5c4c3)c3ccccc23)cc1]

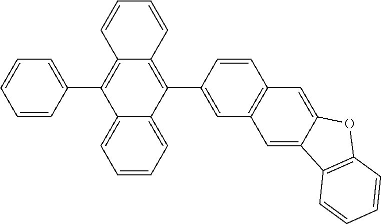 [SMILES: c1ccc(-c2c3ccccc3c(-c3ccc4cc5oc6ccccc6c5cc4c3)c3ccccc23)cc1]

In an especially preferred embodiment, Ant1 and Ant2 are independently selected from the following group of compounds (1-H1-8), with the proviso that at least one of Ant1 and/or Ant2, preferably one of Ant1 and Ant2, contains a deuterated anthracenyl group.

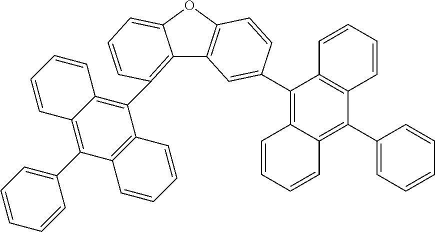 [SMILES: c1ccc(-c2c3ccccc3c(-c3ccc4oc5cccc(-c6c7ccccc7c(-c7ccccc7)c7ccccc67)c5c4c3)c3ccccc23)cc1]

H1

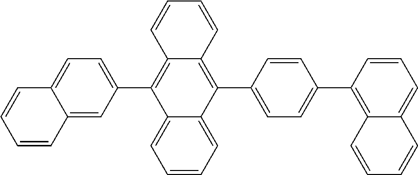 [SMILES: c1ccc2cc(-c3c4ccccc4c(-c4ccc(-c5cccc6ccccc56)cc4)c4ccccc34)ccc2c1]

H2

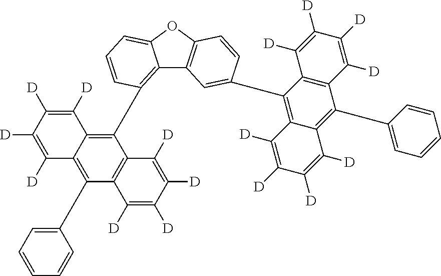 [SMILES: [2H]c1c([2H])c([2H])c2c(Cc3ccc4oc5cccc(Cc6c7c([2H])c([2H])c([2H])c([2H])c7c(Cc7ccccc7)c7c([2H])c([2H])c([2H])c([2H])c67)c5c4c3)c3c([2H])c([2H])c([2H])c([2H])c3c(Cc3ccccc3)c2c1[2H]]

H3

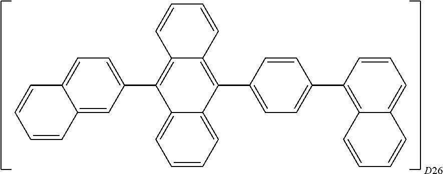

H4

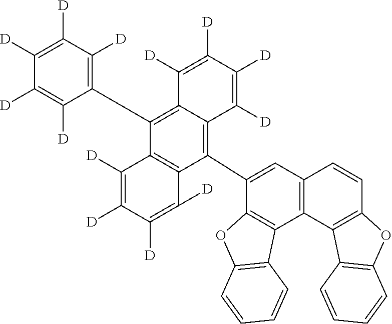 [SMILES: [2H]c1c([2H])c([2H])c(Cc2c3c([2H])c([2H])c([2H])c([2H])c3c(-c3cc4ccc5oc6ccccc6c5c4c4c3oc3ccccc34)c3c([2H])c([2H])c([2H])c([2H])c23)c([2H])c1[2H]]

H5

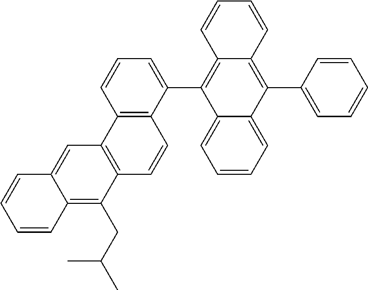 [SMILES: CC(C)Cc1c2ccccc2cc2c1ccc1c(-c3c4ccccc4c(-c4ccccc4)c4ccccc34)cccc12]

H6

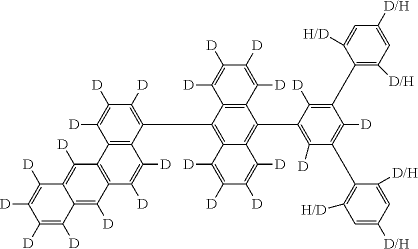

H7

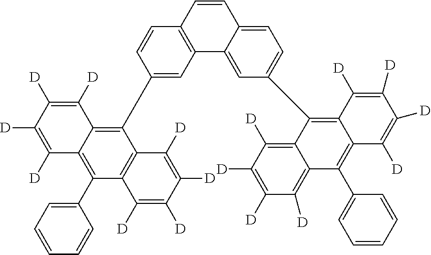 [SMILES: [2H]c1c([2H])c([2H])c2c(-c3ccccc3)c3c([2H])c([2H])c([2H])c([2H])c3c(Cc3ccc4ccc5ccc(Cc6c7c([2H])c([2H])c([2H])c([2H])c7c(-c7ccccc7)c7c([2H])c([2H])c([2H])c([2H])c67)cc5c4c3)c2c1[2H]]

H8

Preferably, Ant1 is present in the mixed host system in a portion equal or superior to 1 wt.-% of the system. More preferably, Ant1 is present in the system in a portion of 1 to 99 wt.-%, preferably 10 to 95 wt.-%, more preferably 20 to 90 wt.-%, in particular 30 to 85 wt.-%, especially 40 to 80 wt.-%, based on the total weight of the mixed host system, respectively.

Preferably, Ant2 is present in the mixed host system in a portion equal or superior to 1 wt.-% of the system. More preferably, Ant2 is present in the system in a portion of 1 to 99 wt.-%, preferably 5 to 90 wt.-%, more preferably 10 to 80 wt.-%, in particular 15 to 70 wt.-%, especially 20 to 60 wt.-%, based on the total weight of the mixed host system, respectively.

### II. Hole-Blocking Compound

The organic electric element further comprises a hole-blocking compound (EG) comprising a six membered ring containing at least one Nitrogen atom, the six membered ring being linked to a moiety of two benzene rings being fused to a central 5-membered heterocycle containing either a Sulphur or an Oxygen atom.

In a preferred embodiment, the hole-blocking compound EG is represented by Formula III:

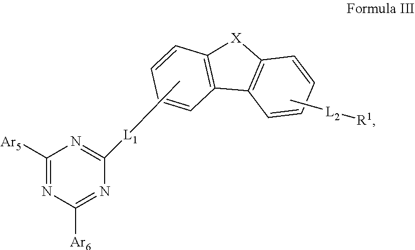

wherein R1 stands on each occurrence for

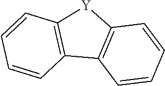

or a triazine moiety;
wherein the heterocycle comprising X and/or the heterocycle comprising Y may be substituted with a group R at any position, R being defined as above;
wherein X stands on each occurrence for O or S, preferably O;
wherein Y stands on each occurrence for O, S, N or for a group of formula (Y-1) or (Y-2)

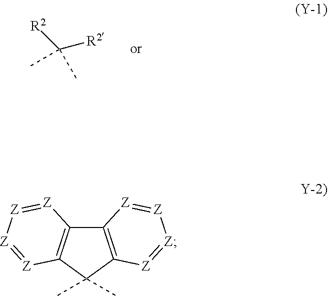

Z is C or N;
R2 and R2′ stand on each occurrence, identically or differently, for a straight, cyclic or branched alkyl chain having 1 to 40 carbon atoms, or an aromatic or heteroaromatic ring system having 5 to 60 aromatic ring atoms; or R2 and R2′ form a ring system;
Ar5 and Ar6 stand on each occurrence, identically or differently, for an aromatic or heteroaromatic ring system having 5 to 60 aromatic ring atoms, which may in each case also be substituted with one or more radicals R″;
R″ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms;
L1 and L2 stand on each occurrence, identically or differently, for a single bond or a substituted or unsubstituted aromatic or heteroaromatic ring system with 5 to 30 aromatic ring atoms.

In preferred embodiment, the hole-blocking compound EG is represented by formula IV:

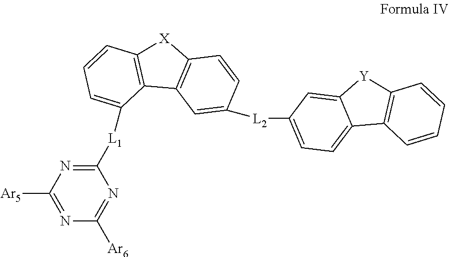

with X, Y, L1, L2, Ar5 and Ar6 being defined as above.

In a preferred embodiment, Ar5 and Ar6 are independently selected from the group consisting of phenyl, biphenyl, terphenyl, quaterphenyl, fluorene, spirobifluorene, naphthalene, anthracene, phenanthrene, triphenylene, fluoranthene, tetracene, chrysene, benzanthracene, benzophenanthracene, pyrene or perylene, dibenzofuran, carbazole and dibenzothiophene. In an especially preferred embodiment, Ar5 and Ar6 are phenyl.

Suitable examples of compounds of the hole-blocking compound EG are depicted in the table below:

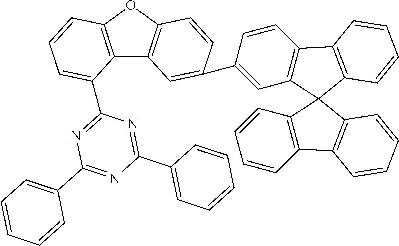 [SMILES: c1ccc(-c2nc(-c3ccccc3)nc(-c3cccc4oc5ccc(-c6ccc7c(c6)C6(c8ccccc8-c8ccccc86)c6ccccc6-7)cc5c34)n2)cc1]

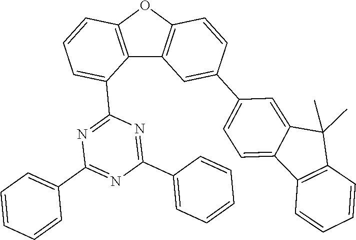 [SMILES: CC1(C)c2ccccc2-c2ccc(-c3ccc4oc5cccc(-c6nc(-c7ccccc7)nc(-c7ccccc7)n6)c5c4c3)cc21]

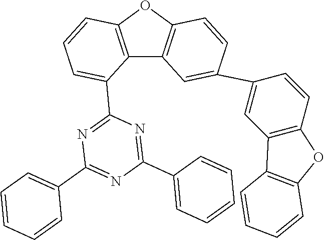 [SMILES: c1ccc(-c2nc(-c3ccccc3)nc(-c3cccc4oc5ccc(-c6ccc7oc8ccccc8c7c6)cc5c34)n2)cc1]

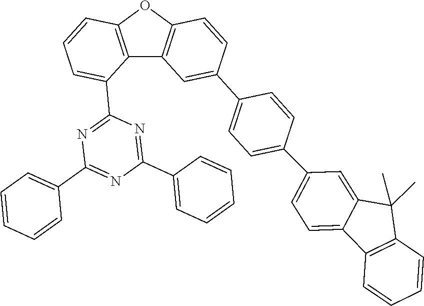 [SMILES: CC1(C)c2ccccc2-c2ccc(-c3ccc(-c4ccc5oc6cccc(-c7nc(-c8ccccc8)nc(-c8ccccc8)n7)c6c5c4)cc3)cc21]

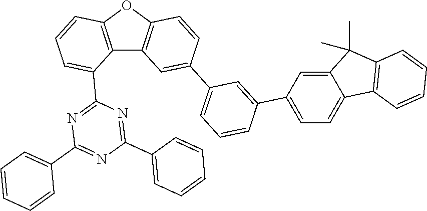 [SMILES: CC1(C)c2ccccc2-c2ccc(-c3cccc(-c4ccc5oc6cccc(-c7nc(-c8ccccc8)nc(-c8ccccc8)n7)c6c5c4)c3)cc21]

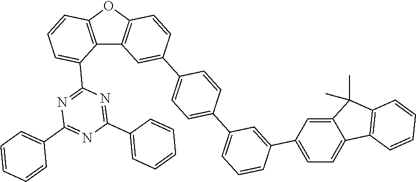 [SMILES: CC1(C)c2ccccc2-c2ccc(-c3cccc(-c4ccc(-c5ccc6oc7cccc(-c8nc(-c9ccccc9)nc(-c9ccccc9)n8)c7c6c5)cc4)c3)cc21]

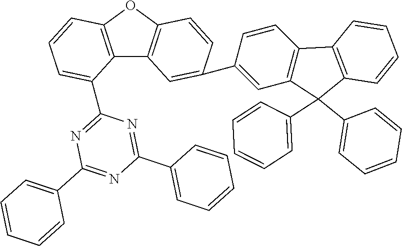 [SMILES: c1ccc(-c2nc(-c3ccccc3)nc(-c3cccc4oc5ccc(-c6ccc7c(c6)C(c6ccccc6)(c6ccccc6)c6ccccc6-7)cc5c34)n2)cc1]

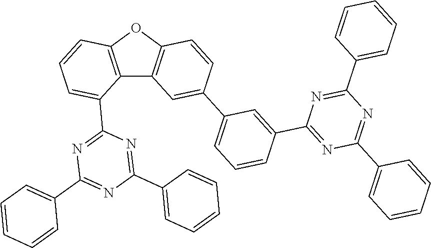 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1]

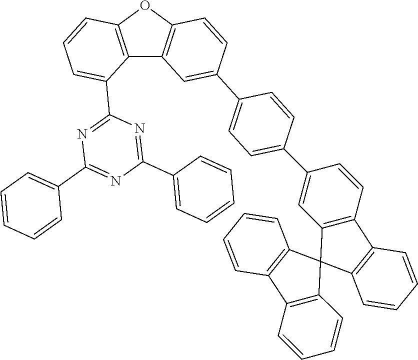 [SMILES: c1ccc(-c2nc(-c3ccccc3)nc(-c3cccc4oc5ccc(-c6ccc(-c7ccc8c(c7)C7(c9ccccc9-c9ccccc97)c7ccccc7-8)cc6)cc5c34)n2)cc1]

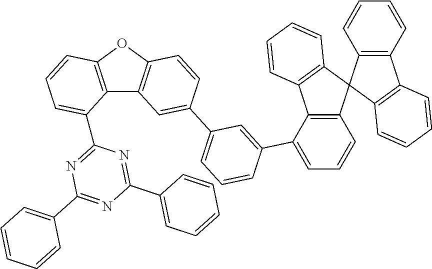 [SMILES: c1ccc(-c2nc(-c3ccccc3)nc(-c3cccc4oc5ccc(-c6cccc(-c7cccc8c7-c7ccccc7C87c8ccccc8-c8ccccc87)c6)cc5c34)n2)cc1]

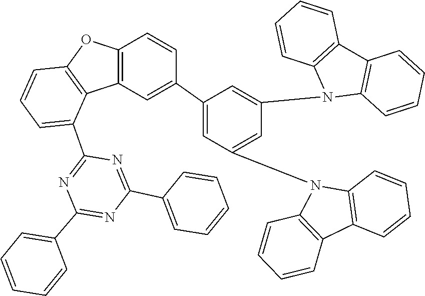 [SMILES: c1ccc(-c2nc(-c3ccccc3)nc(-c3cccc4oc5ccc(-c6cc(-n7c8ccccc8c8ccccc87)cc(-n7c8ccccc8c8ccccc87)c6)cc5c34)n2)cc1]

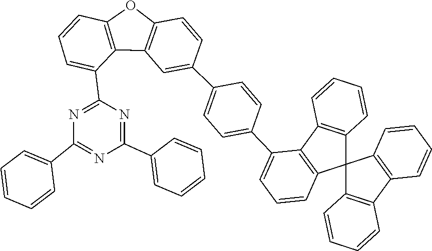 [SMILES: c1ccc(-c2nc(-c3ccccc3)nc(-c3cccc4oc5ccc(-c6ccc(-c7cccc8c7-c7ccccc7C87c8ccccc8-c8ccccc87)cc6)cc5c34)n2)cc1]

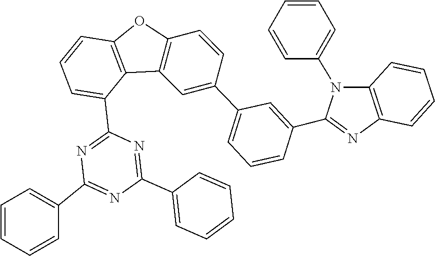 [SMILES: c1ccc(-c2nc(-c3ccccc3)nc(-c3cccc4oc5ccc(-c6cccc(-c7nc8ccccc8n7-c7ccccc7)c6)cc5c34)n2)cc1]

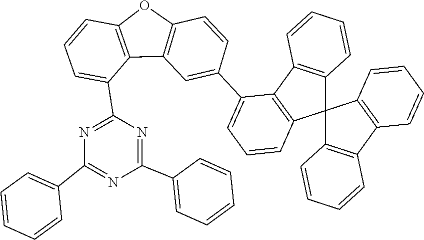 [SMILES: c1ccc(-c2nc(-c3ccccc3)nc(-c3cccc4oc5ccc(-c6cccc7c6-c6ccccc6C76c7ccccc7-c7ccccc76)cc5c34)n2)cc1]

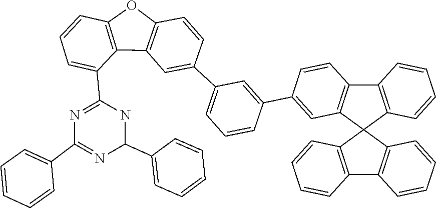

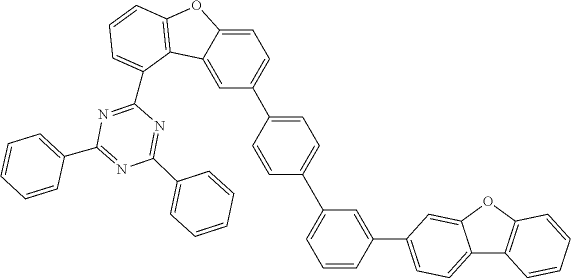 [SMILES: c1ccc(-c2nc(-c3ccccc3)nc(-c3cccc4oc5ccc(-c6ccc(-c7cccc(-c8ccc9c(c8)oc8ccccc89)c7)cc6)cc5c34)n2)cc1]

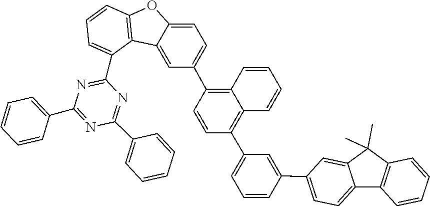 [SMILES: CC1(C)c2ccccc2-c2ccc(-c3cccc(-c4ccc(-c5ccc6oc7cccc(-c8nc(-c9ccccc9)nc(-c9ccccc9)n8)c7c6c5)c5ccccc45)c3)cc21]

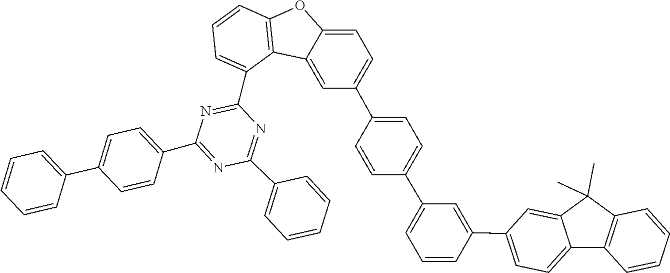 [SMILES: CC1(C)c2ccccc2-c2ccc(-c3cccc(-c4ccc(-c5ccc6oc7cccc(-c8nc(-c9ccccc9)nc(-c9ccc(-c%10ccccc%10)cc9)n8)c7c6c5)cc4)c3)cc21]

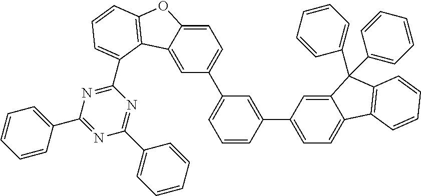 [SMILES: c1ccc(-c2nc(-c3ccccc3)nc(-c3cccc4oc5ccc(-c6cccc(-c7ccc8c(c7)C(c7ccccc7)(c7ccccc7)c7ccccc7-8)c6)cc5c34)n2)cc1]

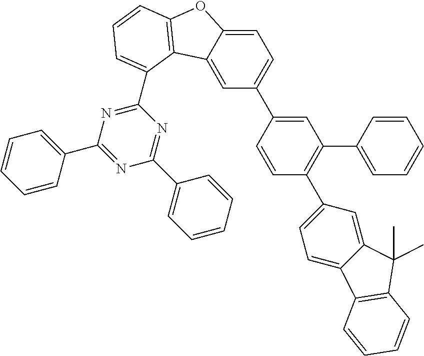 [SMILES: CC1(C)c2ccccc2-c2ccc(-c3ccc(-c4ccc5oc6cccc(-c7nc(-c8ccccc8)nc(-c8ccccc8)n7)c6c5c4)cc3-c3ccccc3)cc21]

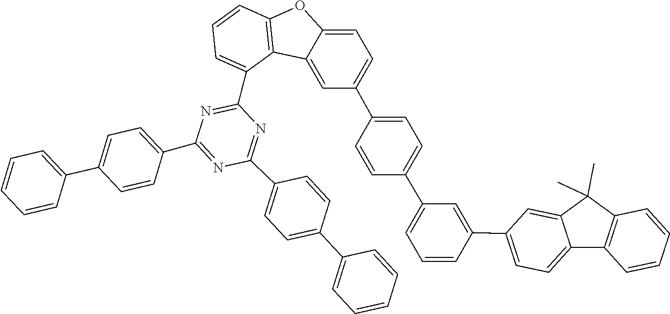 [SMILES: CC1(C)c2ccccc2-c2ccc(-c3cccc(-c4ccc(-c5ccc6oc7cccc(-c8nc(-c9ccc(-c%10ccccc%10)cc9)nc(-c9ccc(-c%10ccccc%10)cc9)n8)c7c6c5)cc4)c3)cc21]

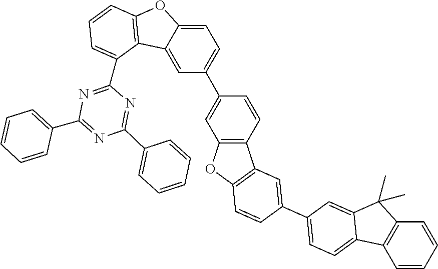 [SMILES: CC1(C)c2ccccc2-c2ccc(-c3ccc4oc5cc(-c6ccc7oc8cccc(-c9nc(-c%10ccccc%10)nc(-c%10ccccc%10)n9)c8c7c6)ccc5c4c3)cc21]

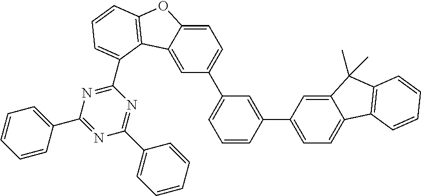 [SMILES: CC1(C)c2ccccc2-c2ccc(-c3cccc(-c4ccc5oc6cccc(-c7nc(-c8ccccc8)nc(-c8ccccc8)n7)c6c5c4)c3)cc21]

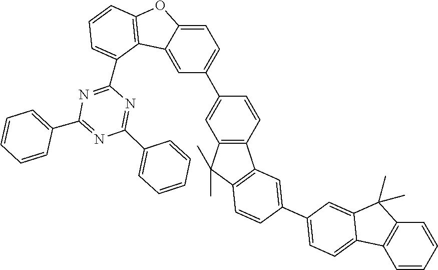 [SMILES: CC1(C)c2ccccc2-c2ccc(-c3ccc4c(c3)-c3ccc(-c5ccc6oc7cccc(-c8nc(-c9ccccc9)nc(-c9ccccc9)n8)c7c6c5)cc3C4(C)C)cc21]

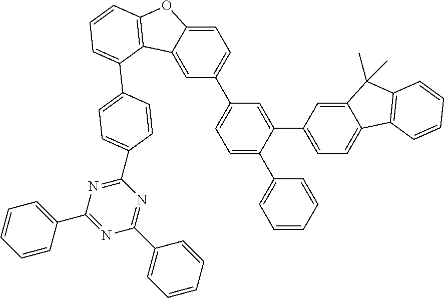 [SMILES: CC1(C)c2ccccc2-c2ccc(-c3cc(-c4ccc5oc6cccc(-c7ccc(-c8nc(-c9ccccc9)nc(-c9ccccc9)n8)cc7)c6c5c4)ccc3-c3ccccc3)cc21]

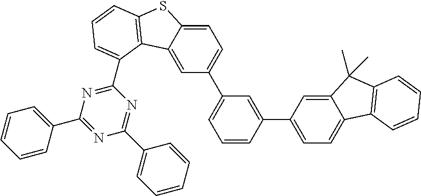 [SMILES: CC1(C)c2ccccc2-c2ccc(-c3cccc(-c4ccc5sc6cccc(-c7nc(-c8ccccc8)nc(-c8ccccc8)n7)c6c5c4)c3)cc21]

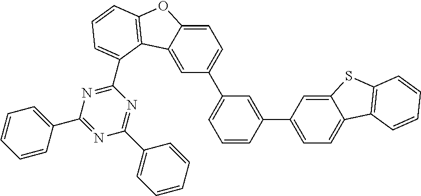 [SMILES: c1ccc(-c2nc(-c3ccccc3)nc(-c3cccc4oc5ccc(-c6cccc(-c7ccc8c(c7)sc7ccccc78)c6)cc5c34)n2)cc1]

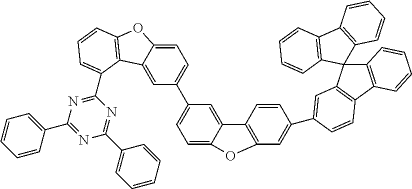 [SMILES: c1ccc(-c2nc(-c3ccccc3)nc(-c3cccc4oc5ccc(-c6ccc7oc8cc(-c9ccc%10c(c9)C9(c%11ccccc%11-c%11ccccc%119)c9ccccc9-%10)ccc8c7c6)cc5c34)n2)cc1]

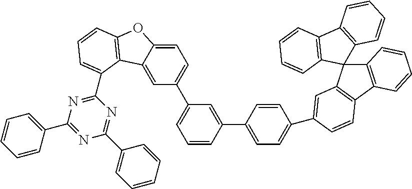 [SMILES: c1ccc(-c2nc(-c3ccccc3)nc(-c3cccc4oc5ccc(-c6cccc(-c7ccc(-c8ccc9c(c8)C8(c%10ccccc%10-c%10ccccc%108)c8ccccc8-9)cc7)c6)cc5c34)n2)cc1]

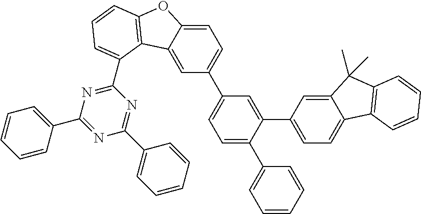 [SMILES: CC1(C)c2ccccc2-c2ccc(-c3cc(-c4ccc5oc6cccc(-c7nc(-c8ccccc8)nc(-c8ccccc8)n7)c6c5c4)ccc3-c3ccccc3)cc21]

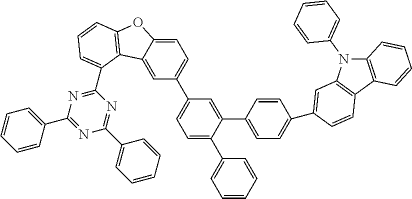 [SMILES: c1ccc(-c2nc(-c3ccccc3)nc(-c3cccc4oc5ccc(-c6ccc(-c7ccccc7)c(-c7ccc(-c8ccc9c%10ccccc%10n(-c%10ccccc%10)c9c8)cc7)c6)cc5c34)n2)cc1]

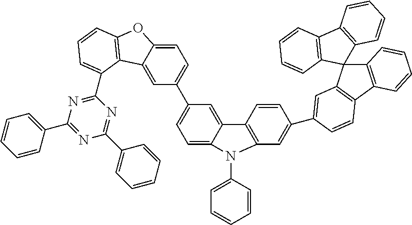 [SMILES: c1ccc(-c2nc(-c3ccccc3)nc(-c3cccc4oc5ccc(-c6ccc7c(c6)c6ccc(-c8ccc9c(c8)C8(c%10ccccc%10-c%10ccccc%108)c8ccccc8-9)cc6n7-c6ccccc6)cc5c34)n2)cc1]

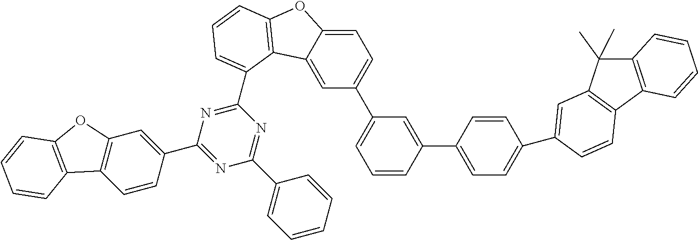 [SMILES: CC1(C)c2ccccc2-c2ccc(-c3ccc(-c4cccc(-c5ccc6oc7cccc(-c8nc(-c9ccccc9)nc(-c9ccc%10c(c9)oc9ccccc9%10)n8)c7c6c5)c4)cc3)cc21]

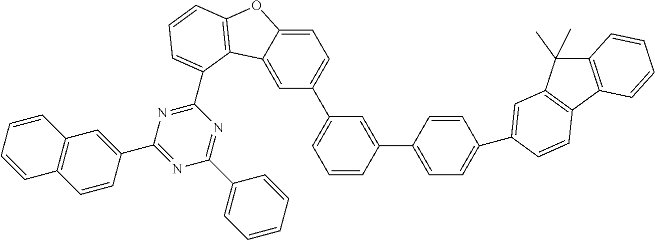 [SMILES: CC1(C)c2ccccc2-c2ccc(-c3ccc(-c4cccc(-c5ccc6oc7cccc(-c8nc(-c9ccccc9)nc(-c9ccc%10ccccc%10c9)n8)c7c6c5)c4)cc3)cc21]

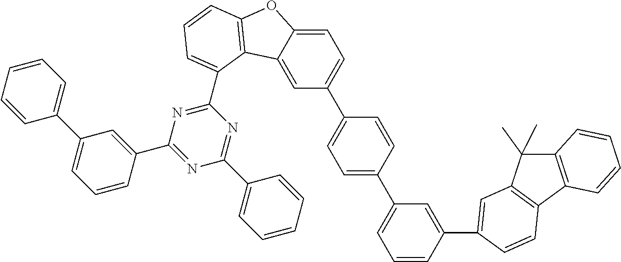 [SMILES: CC1(C)c2ccccc2-c2ccc(-c3cccc(-c4ccc(-c5ccc6oc7cccc(-c8nc(-c9ccccc9)nc(-c9cccc(-c%10ccccc%10)c9)n8)c7c6c5)cc4)c3)cc21]

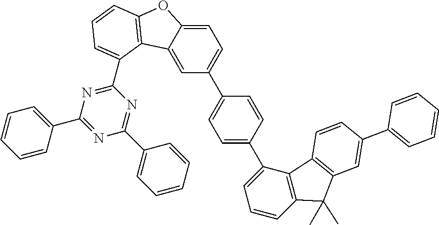 [SMILES: CC1(C)c2cc(-c3ccccc3)ccc2-c2c(-c3ccc(-c4ccc5oc6cccc(-c7nc(-c8ccccc8)nc(-c8ccccc8)n7)c6c5c4)cc3)cccc21]

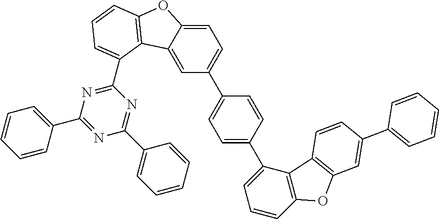 [SMILES: c1ccc(-c2ccc3c(c2)oc2cccc(-c4ccc(-c5ccc6oc7cccc(-c8nc(-c9ccccc9)nc(-c9ccccc9)n8)c7c6c5)cc4)c23)cc1]

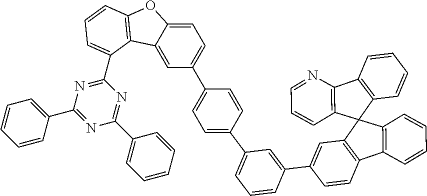 [SMILES: c1ccc(-c2nc(-c3ccccc3)nc(-c3cccc4oc5ccc(-c6ccc(-c7cccc(-c8ccc9c(c8)C8(c%10ccccc%10-9)c9ccccc9-c9ncccc98)c7)cc6)cc5c34)n2)cc1]

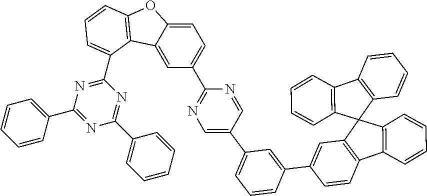 [SMILES: c1ccc(-c2nc(-c3ccccc3)nc(-c3cccc4oc5ccc(-c6ncc(-c7cccc(-c8ccc9c(c8)C8(c%10ccccc%10-c%10ccccc%108)c8ccccc8-9)c7)cn6)cc5c34)n2)cc1]

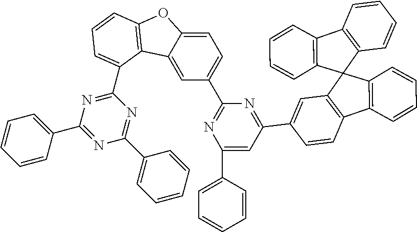 [SMILES: c1ccc(-c2cc(-c3ccc4c(c3)C3(c5ccccc5-c5ccccc53)c3ccccc3-4)nc(-c3ccc4oc5cccc(-c6nc(-c7ccccc7)nc(-c7ccccc7)n6)c5c4c3)n2)cc1]

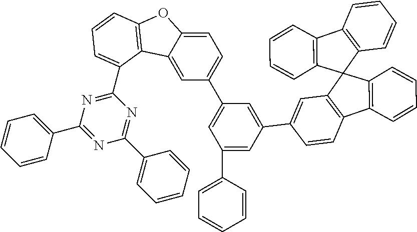 [SMILES: c1ccc(-c2cc(-c3ccc4c(c3)C3(c5ccccc5-c5ccccc53)c3ccccc3-4)cc(-c3ccc4oc5cccc(-c6nc(-c7ccccc7)nc(-c7ccccc7)n6)c5c4c3)c2)cc1]

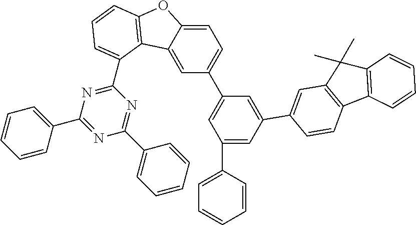 [SMILES: CC1(C)c2ccccc2-c2ccc(-c3cc(-c4ccccc4)cc(-c4ccc5oc6cccc(-c7nc(-c8ccccc8)nc(-c8ccccc8)n7)c6c5c4)c3)cc21]

In a preferred embodiment, the hole-blocking compound EG is selected from the group of consisting of compounds EG1 to EG6:

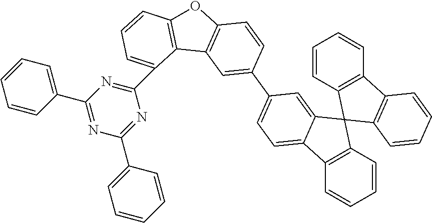 [SMILES: c1ccc(-c2nc(-c3ccccc3)nc(-c3cccc4oc5ccc(-c6ccc7c(c6)C6(c8ccccc8-c8ccccc86)c6ccccc6-7)cc5c34)n2)cc1]

EG1

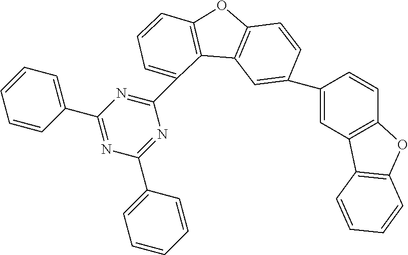 [SMILES: c1ccc(-c2nc(-c3ccccc3)nc(-c3cccc4oc5ccc(-c6ccc7oc8ccccc8c7c6)cc5c34)n2)cc1]

EG2

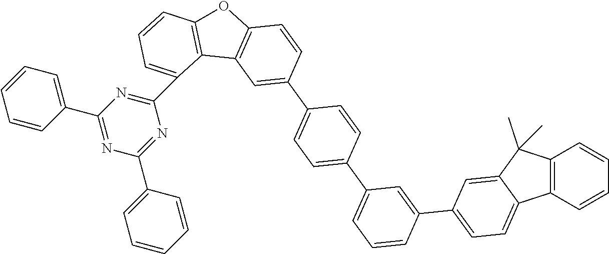 [SMILES: CC1(C)c2ccccc2-c2ccc(-c3cccc(-c4ccc(-c5ccc6oc7cccc(-c8nc(-c9ccccc9)nc(-c9ccccc9)n8)c7c6c5)cc4)c3)cc21]

EG3

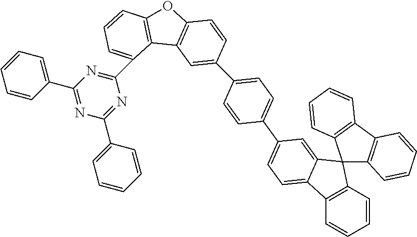 [SMILES: c1ccc(-c2nc(-c3ccccc3)nc(-c3cccc4oc5ccc(-c6ccc(-c7ccc8c(c7)C7(c9ccccc9-c9ccccc97)c7ccccc7-8)cc6)cc5c34)n2)cc1]

EG4

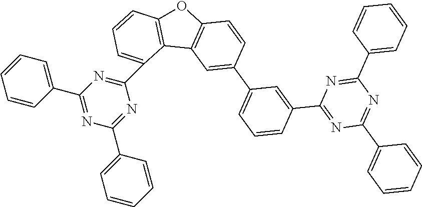 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1]

EG5

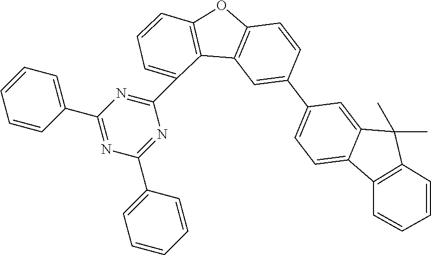 [SMILES: CC1(C)c2ccccc2-c2ccc(-c3ccc4oc5cccc(-c6nc(-c7ccccc7)nc(-c7ccccc7)n6)c5c4c3)cc21]

EG6

Apart from the mixed host system, the light-emitting layer of the organic electric element of the present invention further comprises a dopant, preferably a fluorescent emitter, in particular selected from the group consisting of
an arylamine containing three substituted or unsubstituted aromatic or heteroaromatic ring systems bonded directly to the nitrogen;
a bridged triarylamine;
a condensed aromatic or heteroaromatic ring system having at least 14 aromatic ring atoms;
an indenofluorene, indenofluorenamine or indenofluorenediamine;
a benzoindonofluorene, benzoindenofluorenamine or benzoindenofluorenediamine;
a dibenzoindenofluorene, dibenzoindenofluorenamine or dibenzoindenofluorenediamine;
an indenofluorene containing a condensed aryl group having at least 10 aromatic ring atoms;
a bisindenoindenofluorene;
an indenodibenzofuran; indenofluorenamine or indenofluorenediamine;
a fluorene dimer;
a phenoxazine; and
a boron derivative.

Preferably, the light-emitting layer does not comprise a phosphorescent emitter as dopant material.

The organic electric element of the present invention is preferably selected from organic electroluminescent device (OLEDs), organic integrated circuits, organic field-effect transistors, organic thin-film transistors, organic light-emitting transistors, organic solar cells, dye-sensitised organic solar cells, organic optical detectors, organic photoreceptors, organic field-quench devices, light-emitting electrochemical cells, organic laser diodes and organic plasmon emitting devices. More preferably, the electronic device is an organic electroluminescent device (OLED), an organic solar cell, an organic photo conductor, an organic transistor or an element for monochromatic or white illumination.

The organic electric element according to the invention further comprises a cathode and an anode. Apart from these additional layers, it may also comprise further layers, for example in each case one or more hole-injection layers, hole-transport layers, electron-transport layers, electron-injection layers, exciton-blocking layers, electron-blocking layers and/or charge-generation layers. It is likewise possible for interlayers, which have, for example, an exciton-blocking function, to be introduced between two emitting layers. However, it should be pointed out, that each of these layers does not necessarily have to be present. The organic electric element here may comprise one emitting layer or a plurality of emitting layers. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. Particular preference is given to systems having three emitting layers, where the three layers exhibit blue, green and orange or red emission (for the basic structure see, for example, WO 2005/011013). These can be fluorescent or phosphorescent emission layers or hybrid systems, in which fluorescent and phosphorescent emission layers are combined with one another.

The electronic device concerned may comprise a single emitting layer comprising the mixed host system according to the invention or it may comprise two or more emitting layers.

The cathode of the organic electric element preferably comprises metals having a low work function, metal alloys or multi-layered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multi-layered structures, further metals which have a relatively high work function, such as, for example, Ag or Al, can also be used in addition to the said metals, in which case combinations of the metals, such as, for example, Ca/Ag, Mg/Ag or Ag/Ag, are generally used. It may also be preferred to introduce a thin interlayer of a material having a high dielectric constant between a metallic cathode and the organic semiconductor. Suitable for this purpose are, for example, alkali metal fluorides or alkaline-earth metal fluorides, but also the corresponding oxides or carbonates (for example LiF, Li₂O, BaF₂, MgO, NaF, CsF, Cs₂CO₃, etc.). Furthermore, lithium quinolinate (LiQ) can be used for this purpose. The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order to facilitate either irradiation of the organic material (organic solar cells) or the coupling-out of light (OLEDs, O-lasers). Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

Another aspect of the present invention is a process for the production of an organic electric element of the present invention. In the process for the production of the electric element, the light-emitting layer is preferably formed by a solution process selected from flood coating, dip coating, spray coating, spin coating, screen printing, relief printing, gravure printing, roller coating, inkjet printing, rotary printing, flexographic printing, offset printing, slot die coating or nozzle printing. Furthermore, the hole-blocking layer is preferably formed by a thermal evaporation process.

In a further aspect, the present invention relates to an electronic device comprising a display device comprising an organic electric element according to the invention.

The present invention is described in more detail with reference to the following examples which are by no means to be understood as limiting the scope or spirit of the invention.

### EXAMPLES

The production of solution-based OLEDs has already been described many times in the literature, for example in WO 2004/037887 and WO 2010/097155. The process is adapted to the circumstances described below (layer-thickness variation, materials).

The inventive material combinations are used in the following layer sequence:
substrate,
ITO (50 nm),
Hole injection layer (HIL, 20 nm),
hole transport layer (HTL, 20 nm),
emission layer (EML, 40 nm),
hole-blocking layer (HBL, 5 nm),
electron-transport layer (ETL, 45 nm),
electron-injection layer (EIL, 1 nm),
cathode (Al, 100 nm).

Glass plates coated with structured ITO (indium tin oxide) in a thickness of 50 nm serve as substrate. These are coated with an HIL material, a hole-transporting, cross-linkable polymer and a p-doped salt as described, e.g. in WO2016/107668, WO2013/081052 and EP2325190. Both materials are dissolved in toluene, so that the solution typically has a solid content of approx. 6 g/I if, as here, the layer thickness of 20 nm which is typical for a device is to be achieved by means of spin coating. The layers are applied by spin coating in an air atmosphere and dried by heating at 225° C. for 30 min.

The hole-transport layer (HTL) is the polymer of the structure HTM shown in Table 1, which was synthesised in accordance with WO2018/114882. The polymer is dissolved in toluene, so that the solution typically has a solid content of approx. 5 g/l if, as here, the layer thickness of 20 nm which is typical for a device is to be achieved by means of spin coating. The layers are applied by spin coating in an inert-gas atmosphere, in the present case argon, and dried by heating at 220° C. for 30 min.

TABLE 1
Structural formulae of the materials of the solution processed layers

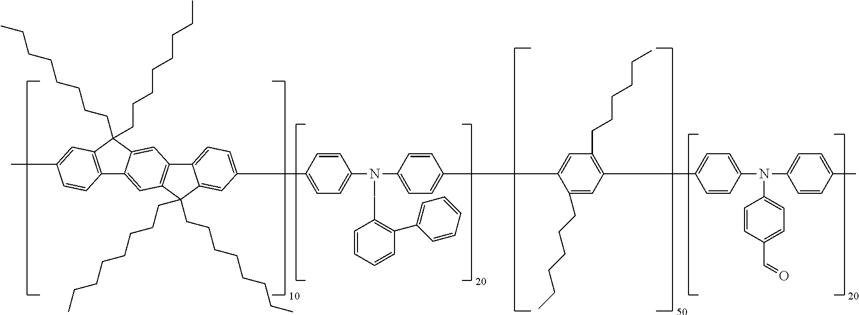

HTM

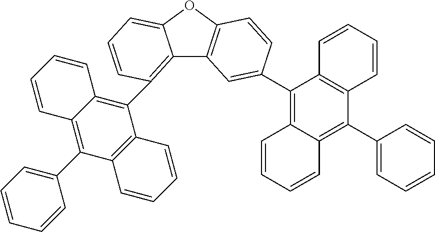 [SMILES: c1ccc(-c2c3ccccc3c(-c3ccc4oc5cccc(-c6c7ccccc7c(-c7ccccc7)c7ccccc67)c5c4c3)c3ccccc23)cc1]

H1

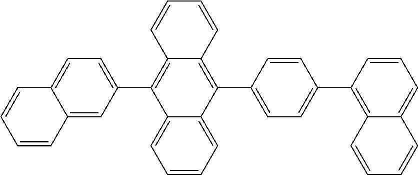 [SMILES: c1ccc2cc(-c3c4ccccc4c(-c4ccc(-c5cccc6ccccc56)cc4)c4ccccc34)ccc2c1]

CAS: 667940-34-3
H2

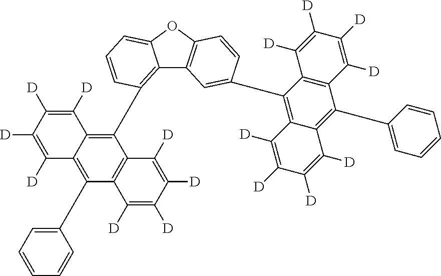 [SMILES: [2H]c1c([2H])c([2H])c2c(Cc3ccc4oc5cccc(Cc6c7c([2H])c([2H])c([2H])c([2H])c7c(Cc7ccccc7)c7c([2H])c([2H])c([2H])c([2H])c67)c5c4c3)c3c([2H])c([2H])c([2H])c([2H])c3c(Cc3ccccc3)c2c1[2H]]

H3

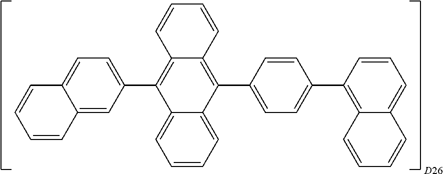

CAS: 1272637-92-9
H4

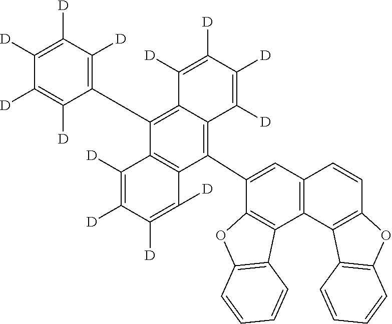 [SMILES: [2H]c1c([2H])c([2H])c(Cc2c3c([2H])c([2H])c([2H])c([2H])c3c(-c3cc4ccc5oc6ccccc6c5c4c4c3oc3ccccc34)c3c([2H])c([2H])c([2H])c([2H])c23)c([2H])c1[2H]]

H5

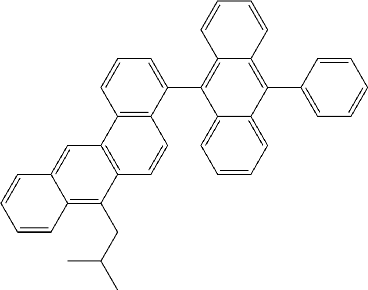 [SMILES: CC(C)Cc1c2ccccc2cc2c1ccc1c(-c3c4ccccc4c(-c4ccccc4)c4ccccc34)cccc12]

CAS: 1818872-85-3
H6

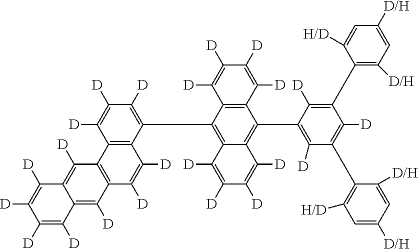

H7

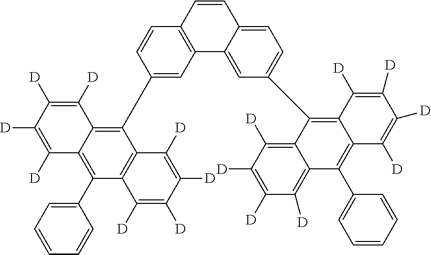 [SMILES: [2H]c1c([2H])c([2H])c2c(-c3ccccc3)c3c([2H])c([2H])c([2H])c([2H])c3c(Cc3ccc4ccc5ccc(Cc6c7c([2H])c([2H])c([2H])c([2H])c7c(-c7ccccc7)c7c([2H])c([2H])c([2H])c([2H])c67)cc5c4c3)c2c1[2H]]

H8

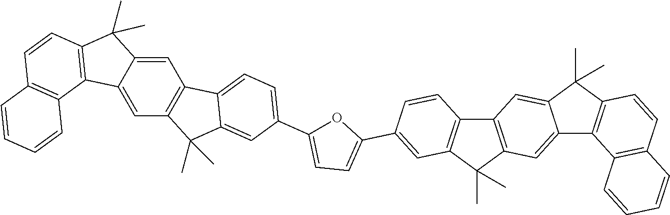 [SMILES: CC1(C)c2cc(-c3ccc(-c4ccc5c(c4)C(C)(C)c4cc6c(cc4-5)C(C)(C)c4ccc5ccccc5c4-6)o3)ccc2-c2cc3c(cc21)-c1c(ccc2ccccc12)C3(C)C]

D

The emission layer is composed of a mixture of two host materials and the emitting material (D). The weight ratios are indicated in Table 3. The mixture for the emission layer is dissolved in toluene. The solids content of such solutions is about 14 mg/ml if, as here, the layer thickness of 40 nm which is typical for a device is to be achieved by means of spin coating. The layers are applied by spin coating in an inert-gas atmosphere and dried by heating at 150° C. for 10 minutes.

The materials for the hole-blocking layer and the electron-transporting layer are likewise applied by thermal vapour deposition in a vacuum chamber and are shown in Table 2. The constitution of the hole-blocking layer is shown in Table 3, whereas the electron-transporting layer consists of the two materials ETM and LiQ, which are mixed with one another in a proportion by volume of 50% of ETM and 50% of LiQ by co-evaporation. The electron-injection layer is formed by 1 nm of evaporated LiQ. The cathode is formed by thermal evaporation of an aluminium layer with a thickness of 100 nm.

TABLE 2
Structural formulae of the materials used for the evaporated layers

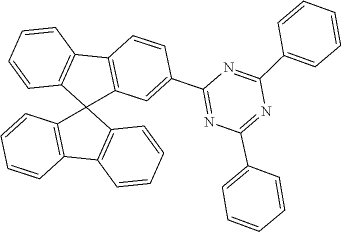 [SMILES: c1ccc(-c2nc(-c3ccccc3)nc(-c3ccc4c(c3)C3(c5ccccc5-c5ccccc53)c3ccccc3-4)n2)cc1]

SdT

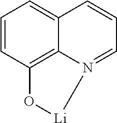

LiQ

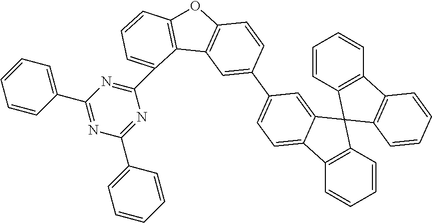 [SMILES: c1ccc(-c2nc(-c3ccccc3)nc(-c3cccc4oc5ccc(-c6ccc7c(c6)C6(c8ccccc8-c8ccccc86)c6ccccc6-7)cc5c34)n2)cc1]

CAS 1822310-88-2
EG1

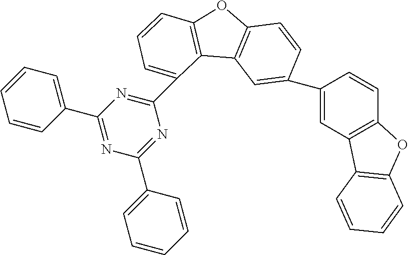 [SMILES: c1ccc(-c2nc(-c3ccccc3)nc(-c3cccc4oc5ccc(-c6ccc7oc8ccccc8c7c6)cc5c34)n2)cc1]

CAS 1822310-90-6
EG2

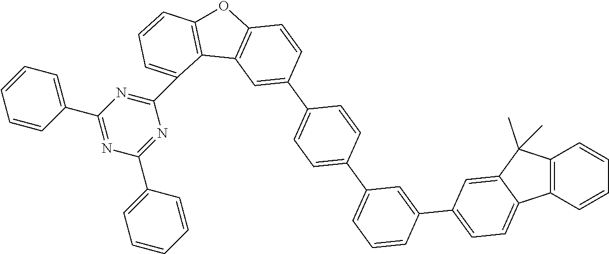 [SMILES: CC1(C)c2ccccc2-c2ccc(-c3cccc(-c4ccc(-c5ccc6oc7cccc(-c8nc(-c9ccccc9)nc(-c9ccccc9)n8)c7c6c5)cc4)c3)cc21]

EG3

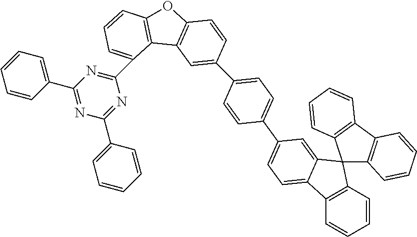 [SMILES: c1ccc(-c2nc(-c3ccccc3)nc(-c3cccc4oc5ccc(-c6ccc(-c7ccc8c(c7)C7(c9ccccc9-c9ccccc97)c7ccccc7-8)cc6)cc5c34)n2)cc1]

CAS 2392900-36-4
EG4

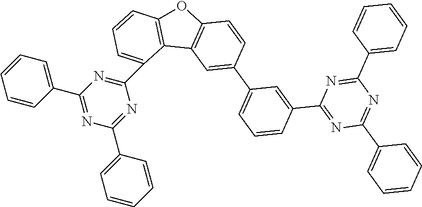 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1]

CAS 2140927-85-9
EG5

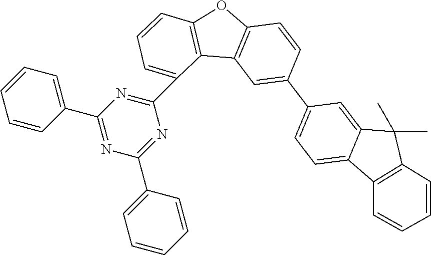 [SMILES: CC1(C)c2ccccc2-c2ccc(-c3ccc4oc5cccc(-c6nc(-c7ccccc7)nc(-c7ccccc7)n6)c5c4c3)cc21]

CAS 2173554-80-6
EG6

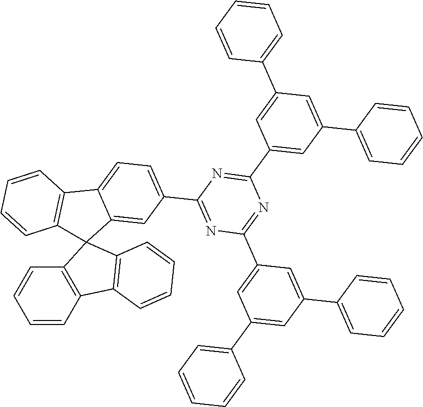 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ETM

### Synthesis of EG3

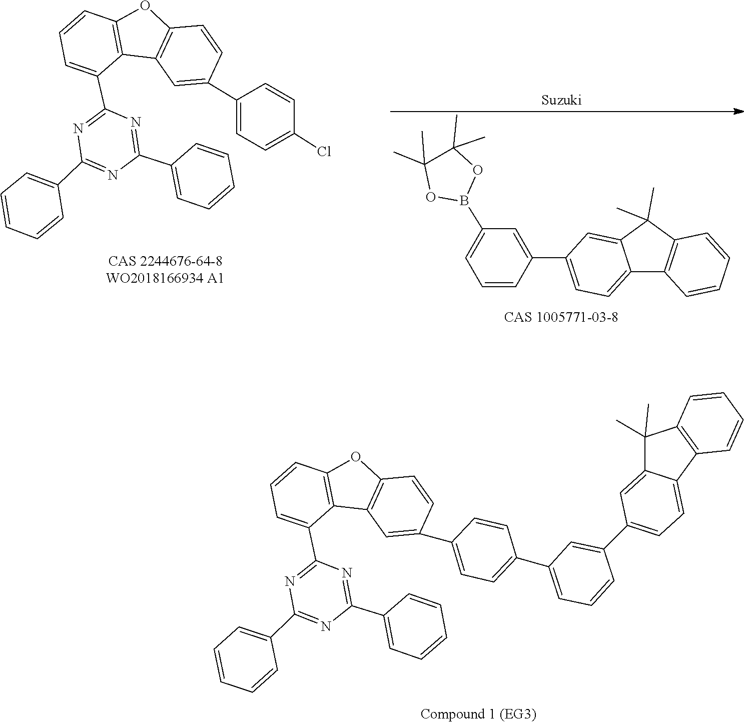 [SMILES: Clc1ccc(-c2ccc3oc4cccc(-c5nc(-c6ccccc6)nc(-c6ccccc6)n5)c4c3c2)cc1 ; CC1(C)c2ccccc2-c2ccc(-c3cccc(B4OC(C)(C)C(C)(C)O4)c3)cc21 ; CC1(C)c2ccccc2-c2ccc(-c3cccc(-c4ccc(-c5ccc6oc7cccc(-c8nc(-c9ccccc9)nc(-c9ccccc9)n8)c7c6c5)cc4)c3)cc21]

15.0 g (28.15 mmol) CAS2244676-64-8, 11.71 (29.56 mmol) CAS1005771-03-8, 730 mg (0.84 mmol) XPhos palladacycle Gen3 and 30.0 g (56.3 mmol) potassium phosphate mono hydrate are mixed in a 450 ml THF/water (2:1). The mixture is refluxed 18 hours until full conversion. After cooling down to room temperature 300 ml toluene and 100 ml water are added. The organic phase is separated and washed with water (3×150 ml). The organic phase is dried over sodium sulfate and concentrated under reduced pressure. The residue is slurried in 200 ml toluene/ethanol (2:3) and filtered off. The crude material is further purified by crystallization out of toluene and sublimation (380° C.; <7×10⁻⁵ mbar) until a purity of 99.9% by HPLC is achieved.

The OLEDs are characterised by standard methods. For this purpose, the electroluminescence spectra are recorded, the current efficiency (measured in cd/A) and the external quantum efficiency (EQE, measured in percent) as a function of the luminous density assuming Lambert emission characteristics are calculated from current/voltage/luminous density characteristic lines (IUL characteristic lines). The electroluminescence spectra are recorded at a luminous density of 1000 cd/m², and the CIE 1931 x and y colour coordinates are calculated from this data. The lifetime LT95 @ 10 mA/cm² is defined as the time after which the initial luminous density at a constant current density of 10 mA/cm² has dropped by 5%.

The properties of the various OLEDs comprising a mixed host system and a hole-blocking compound according to the invention are summarised in Table 3.

Examples V1 to V3 represent state of the art examples, with example V1 representing the reference with normalized power efficacy in lm/W to 100% as well as normalized LT95@1000 cd/m² to 100%. Examples E1 to E8 represent combinations according to the present invention. All examples according to the present invention show a significant improvement in lifetime compared to the state-of-the-art.

TABLE 3
Device data of the OLEDs

| | EML | | CIE x/y | Im/W | LT95 [h] |
|---|---|---|---|---|---|
| Example | Composition | HBL | @ 1000 cd/m² | | |
| V1 | H1(50%):H2 | SdT | 0.15/0.18 | 6.7 = 100% | 170 = 100% |
| | (45%)D(5%) | | | | |
| V2 | H1(50%):H2 | EG1 | 0.15/0.18 | 7.4 = 110% | 200 = 120% |
| | (45%)D(5%) | | | | |
| V3 | H3(50%):H4 | SdT | 0.15/0.18 | 6.5 = 97% | 250 = 150% |
| | (45%)D(5%) | | | | |
| E1 | H2(50%):H3 | EG1 | 0.15/0.18 | 7.5 = 112% | 340 = 200% |
| | (45%)D(5%) | | | | |
| E2 | H3(50%):H4 | EG2 | 0.15/0.18 | 7.4 = 110% | 360 = 210% |
| | (45%)D(5%) | | | | |
| E3 | H3(50%):H4 | EG3 | 0.15/0.18 | 7.3 = 109% | 370 = 220% |
| | (45%)D(5%) | | | | |
| E4 | H5(50%):H6 | EG2 | 0.15/0.18 | 7.5 = 110% | 340 = 200% |
| | (45%)D(5%) | | | | |
| E5 | H5(50%):H6 | EG5 | 0.15/0.18 | 7.6 = 113% | 340 = 200% |
| | (45%)D(5%) | | | | |
| E6 | H7(50%):H8 | EG3 | 0.15/0.18 | 7.5 = 112% | 380 = 230% |
| | (45%)D(5%) | | | | |
| E7 | H7(50%):H8 | EG4 | 0.15/0.18 | 7.3 = 109% | 340 = 200% |
| | (45%)D(5%) | | | | |
| E8 | H7(50%):H8 | EG6 | 0.15/0.18 | 7.5 = 110% | 360 = 210% |
| | (45%)D(5%) | | | | |

As can be seen from the provided data, the combination of a mixed host system in combination with a hole-blocking layer as defined in the present invention results in organic electric elements with increased lifetime.

1.-12. (canceled)

13. An organic electric element comprising:
an anode;
a cathode;
at least one light-emitting layer between the anode and the cathode, the light emitting layer comprising a mixed host system of a first anthracene compound (Ant1) and a second anthracene compound (Ant2) wherein at least one of Ant1 and Ant2 is deuterated; and
at least one hole-blocking layer between the cathode and the light-emitting layer, the hole-blocking layer comprising at least one hole-blocking compound (EG) comprising a six membered ring containing at least one Nitrogen atom, the six membered ring being linked to a moiety of two benzene rings being fused to a central 5-membered heterocycle containing either a Sulphur or an Oxygen atom.

14. The electric element according to claim 13, wherein Ant1 is represented by formula I: 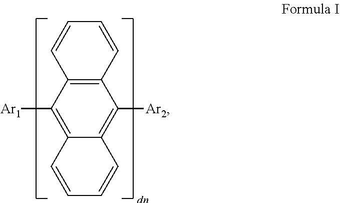
and Ant2 is represented by Formula II 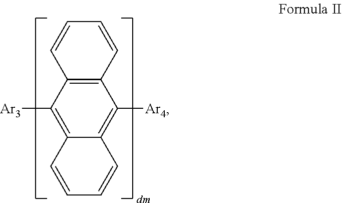
with
d or D depicting the number of deuterium substituents on the anthracenyl group;
n is an integer from 1 to 8;
m is an integer from 0 to 8;
Ar₁, Ar₂, Ar₃ and Ar₄ are, on each occurrence, identically or differently, an aromatic or heteroaromatic ring system having 5 to 60 aromatic ring atoms, which may in each case also be substituted by one or more radicals R;
R stands on each occurrence, identically or differently, for H, D, F, Cl, Br, I, CHO, CN, C(═O)Ar, P(═O)(Ar)₂, S(═O)Ar, S(═O)₂Ar, N(R′)₂, N(Ar)₂, NO₂, Si(R′)₃, B(OR′)₂, OSO₂R′, a straight-chain alkyl, alkoxy or thioalkyl group having 1 to 40 C atoms or branched or a cyclic alkyl, alkoxy or thioalkyl group having 3 to 40 C atoms, each of which may be substituted by one or more radicals R′, where in each case one or more non-adjacent CH₂ groups may be replaced by R′C═CR′, C≡C, Si(R′)₂, Ge(R′)₂, Sn(R′)₂, C═O, C═S, C═Se, P(═O)(R′), SO, SO₂, O, S or CONR′ and where one or more H atoms may be replaced by D, F, Cl, Br, I, CN or NO₂, an aromatic or heteroaromatic ring system having 5 to 60 aromatic ring atoms, which may in each case be substituted by one or more radicals R′, or an aryloxy group having 5 to 60 aromatic ring atoms, which may be substituted by one or more radicals R′; where two adjacent substituents R may form an aliphatic or aromatic ring system together, which may be substituted by one or more radicals R′;
Ar is, on each occurrence, identically or differently, an aromatic or heteroaromatic ring system having 5 to 60 aromatic ring atoms, which may in each case also be substituted by one or more radicals R′;
R′ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms.

15. The electric element according to claim 13, wherein both Ant1 and Ant2 comprise at least on fully deuterated anthracenyl group.

16. The electric element according to claim 13, wherein the hole-blocking compound EG is represented by Formula III: 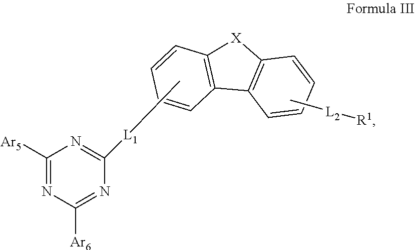
wherein R¹ stands on each occurrence for 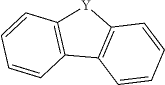
or a triazine moiety;
wherein the heterocycle comprising X and/or the heterocycle comprising Y may be substituted with a group R at any position, R being defined as above;
wherein X stands on each occurrence for O or S, preferably O;
wherein Y stands on each occurrence for O, S, N, 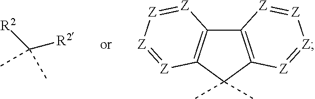
Z is C or N;
R² and R^{2′} stand on each occurrence, identically or differently, for a straight, cyclic or branched alkyl chain having 1 to 40 carbon atoms, or an aromatic or heteroaromatic ring system having 5 to 60 aromatic ring atoms; or R² and R^{2′} form a ring system;
Ar₅ and Ar₆ stand on each occurrence, identically or differently, for an aromatic or heteroaromatic ring system having 5 to 60 aromatic ring atoms, which may in each case also be substituted with one or more radicals R″;
R″ stands on each occurrence, identically or differently, for H, D, F, Cl, Br, I, CN, a straight-chain alkyl, alkoxy or thioalkyl group having 1 to 20 C atoms or branched or cyclic alkyl, alkoxy or thioalkyl group having 3 to 20 C atoms, where in each case one or more non-adjacent CH₂ groups may be replaced by SO, SO₂, O, S and where one or more H atoms may be replaced by D, F, Cl, Br or I, or an aromatic or heteroaromatic ring system having 5 to 24 aromatic ring atoms;
L₁ and L₂ stand on each occurrence, identically or differently, for a single bond or a substituted or unsubstituted aromatic or heteroaromatic ring system with 5 to 30 aromatic ring atoms.

17. The electric element according to claim 13, wherein the hole-blocking compound EG is selected from the group of following formula IV: 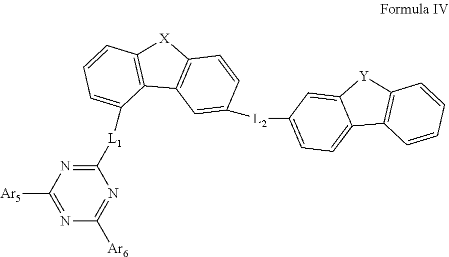
with X, Y, L₁, L₂, Ar₅ and Ar₆ being defined as above.

18. The electric element according to claim 13, wherein Ar₁, Ar₂, Ar₃ and Ar₄ are on occurrence, identically or differently, selected from the group consisting of phenyl, biphenyl, terphenyl, quaterphenyl, fluorene, spirobifluorene, naphthalene, anthracene, phenanthrene, triphenylene, fluoranthene, tetracene, chrysene, benzanthracene, benzophenanthracene, pyrene or perylene, dibenzofuran, carbazole and dibenzothiophene, each of which may be substituted by one or more radicals R as defined above at any free positions.

19. The electric element according to claim 13, wherein Ant1 and Ant2 are independently selected from the group of following formulae: 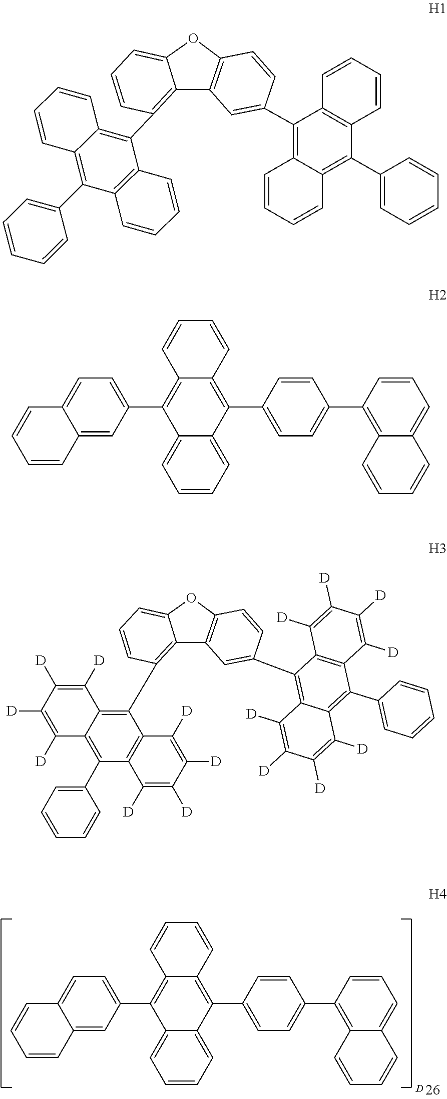 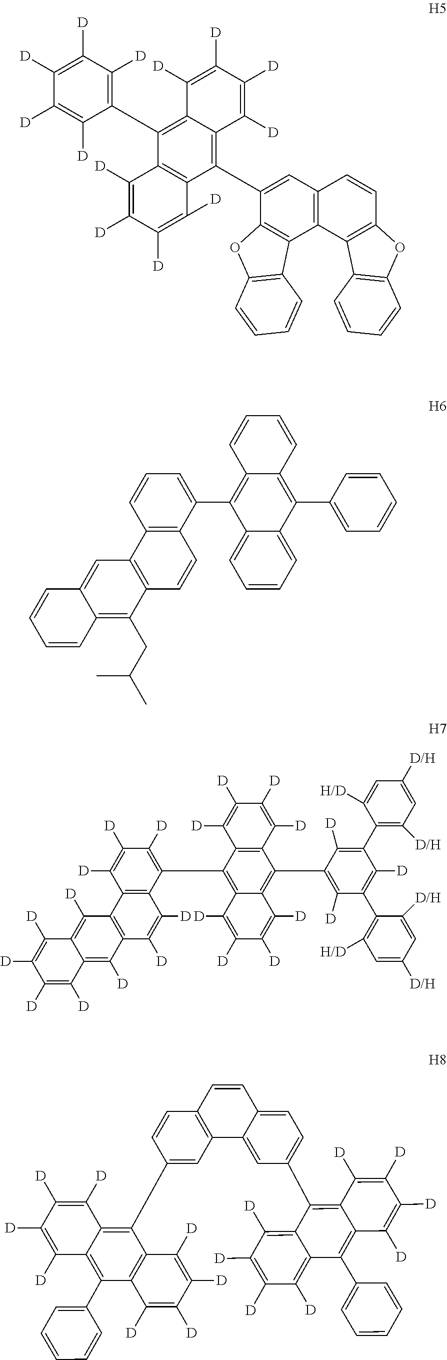
with the proviso that at least one of Ant1 and/or Ant2 contains a deuterated anthracenyl group.

20. The electric element according to claim 13, wherein the light-emitting layer further comprises a dopant, preferably a fluorescent emitter, in particular selected from the group consisting of
an arylamine containing three substituted or unsubstituted aromatic or heteroaromatic ring systems bonded directly to the nitrogen;
a bridged triarylamine;
a condensed aromatic or heteroaromatic ring system having at least 14 aromatic ring atoms;
an indenofluorene, indenofluorenamine or indenofluorenediamine;
a benzoindonofluorene, benzoindenofluorenamine or benzoindenofluorenediamine;
a dibenzoindenofluorene, dibenzoindenofluorenamine or dibenzoindenofluorenediamine;
an indenofluorene containing a condensed aryl group having at least 10 aromatic ring atoms;
a bisindenoindenofluorene;
an indenodibenzofuran; indenofluorenamine or indenofluorenediamine;
a fluorene dimer;
a phenoxazine; and
a boron derivative.

21. The electric element according to claim 13, wherein the light-emitting layer does not comprise a phosphorescent emitter as a dopant material.

22. The electric element according to claim 13, wherein the electric element is an organic light emitting diode, an organic solar cell, an organic photo conductor, an organic transistor or an element for monochromatic or white illumination.

23. Process for the production of the electric element according to claim 13, wherein the at least one light-emitting layer is formed by a process selected from flood coating, dip coating, spray coating, spin coating, screen printing, relief printing, gravure printing, roller coating, inkjet printing, rotary printing, flexographic printing, offset printing, slot die coating or nozzle printing and the at least one hole-blocking layer is formed by a thermal evaporation process.

24. An electronic device comprising a display device and a control unit for controlling the display device, wherein the display device comprises an organic electric element according to claim 13.
